(19) United States
(12) Patent Application Publication
(10) Pub. No.: US 2016/0149043 A1
(43) Pub. Date: May 26, 2016

(54) THIN FILM TRANSISTOR SUBSTRATE AND METHOD OF MANUFACTURING THE SAME

(71) Applicant: Samsung Display Co., Ltd., Yongin-si (KR)

(72) Inventors: Young-Joo CHOI, Suwon-si (KR); Hyeon-Jun LEE, Hwaseong-si (KR); Byung-Gyu PARK, Suwon-si (KR); Eun-Hye PARK, Incheon (KR); Byung-Hwan CHU, Seoul (KR)

(21) Appl. No.: 14/805,069

(22) Filed: Jul. 21, 2015

(30) Foreign Application Priority Data
Nov. 24, 2014 (KR) 10-2014-0164697

(51) Int. Cl. H01L 29/786; H01L 21/311; H01L 29/66; H01L 21/02; H01L 27/12; H01L 23/532

(52) U.S. Cl. CPC H01L 29/7869; H01L 27/1225; H01L 27/124; H01L 23/53257; H01L 29/66969; H01L 27/1288; H01L 21/02164; H01L 21/0217; H01L 21/31111

(57) ABSTRACT

A thin film transistor substrate includes a gate metal pattern comprising a gate line extending in a first direction and a gate electrode electrically connected to the gate line, an active pattern overlapping the gate electrode, an etch-stop layer disposed on the active pattern and having a first through hole and a second through hole adjacent to the first through hole, a data metal pattern comprising a data line extending in a second direction crossing the first direction, a source electrode electrically connected to the active pattern through the first through hole and a drain electrode electrically connected to the active pattern through the second through hole and a first passivation layer disposed on the data metal pattern.

### CLAIM OF PRIORITY

This application claims the priority of and all the benefits accruing under 35 U.S.C. §119 to Korean Patent Application No. 10-2014-0164697, filed on Nov. 24, 2014 in the Korean Intellectual Property Office (“KIPO”), the contents of which are herein incorporated by reference in their entireties.

### BACKGROUND OF THE INVENTION

1. Field of Disclosure

Exemplary embodiments of the present inventive concept relate to a thin film transistor. More particularly, exemplary embodiments relate to a thin film transistor substrate that may be used for a display device, and a method of manufacturing the thin film transistor substrate.

2. Description of the Related Art

Generally, a thin film transistor for driving a pixel unit in a display device includes a gate electrode, a source electrode, a drain electrode, and an active pattern forming a channel between the source electrode and the drain electrode. The active pattern includes a semiconductor layer including amorphous silicon, polycrystalline silicon, oxide semiconductor, or the like.

Amorphous silicon has a relatively low electron mobility, which may be about 1 to about 10 cm²/V, so that a thin film transistor including amorphous silicon has relatively low driving characteristics. In contrast, polycrystalline silicon has a relatively high electron mobility, which may be about 10 to about hundreds cm²/V. However, a crystallization process is required for forming polycrystalline silicon. Thus, it is difficult to form a uniform polycrystalline silicon layer on a large-sized substrate, and resulting that manufacturing costs are high. Oxide semiconductors may be formed through a low-temperature process, and may be easily large-scaled, and have a high electron mobility. Thus, research is actively being conducted on thin film transistors which include an oxide semiconductor.

However, when a thin film transistor substrate is manufactured, many masks are required. Therefore, manufacturing cost may be increased.

### SUMMARY OF THE INVENTION

Exemplary embodiments of the present inventive concept provide a method of manufacturing a thin film transistor substrate capable of decreasing the number of mask.

Exemplary embodiments of the present inventive concept further provide a thin film transistor substrate manufactured by the method.

In an exemplary embodiment of a thin film transistor substrate according to the present inventive concept, the thin film transistor substrate includes a gate metal pattern comprising a gate line extending in a first direction and a gate electrode electrically connected to the gate line, an active pattern overlapping the gate electrode, an etch-stop layer disposed on the active pattern and having a first through hole and a second through hole adjacent to the first through hole, a data metal pattern comprising a data line extending in a second direction crossing the first direction, a source electrode electrically connected to the active pattern through the first through hole and a drain electrode electrically connected to the active pattern through the second through hole and a first passivation layer disposed on the data metal pattern.

In an exemplary embodiment, the thin film transistor substrate may further include a gate pad disposed on the same layer as the gate metal pattern and electrically connected to the gate line and a signal line disposed on the same layer as the data metal pattern and contacted with the gate pad to apply a gate signal to the gate pad.

In an exemplary embodiment, the thin film transistor substrate may further include a gate insulation layer covering the gate line and the gate electrode. The etch-stop layer may cover the gate insulation layer and the active pattern.

In an exemplary embodiment, the etch-stop layer may include a silicon oxide or a silicon nitride.

In an exemplary embodiment, the data metal pattern may have a single-layered structure or a multiple-layered structure comprising titanium.

In an exemplary embodiment, the active pattern may include an oxide semiconductor.

In an exemplary embodiment, the first passivation layer may include an inorganic insulating material.

In an exemplary embodiment, the thin film transistor substrate may further include a common electrode disposed on the first passivation layer, a second passivation layer disposed on the common electrode and a pixel electrode disposed on the second passivation layer and electrically connected to the drain electrode.

In an exemplary embodiment, the common electrode may form an under-cut structure with the second passivation layer.

In an exemplary embodiment of a method of manufacturing a thin film transistor substrate according to the present inventive concept, the method includes forming a gate metal pattern on a base substrate, the gate metal pattern comprising a gate line extending in a first direction and a gate electrode electrically connected to the gate line, forming a gate insulation layer covering the gate line and the gate electrode, forming an active pattern overlapping the gate electrode, forming an etch-stop layer covering the gate insulation layer and the active pattern, forming a data metal pattern comprising a data line extending in a second direction crossing the first direction, a source electrode electrically connected to the active pattern through the first through hole and a drain electrode electrically connected to the active pattern through the second through hole and forming a first passivation layer on the data metal pattern.

In an exemplary embodiment, the method may further include forming a common electrode on the first passivation layer, forming a second passivation layer on the common electrode and forming a pixel electrode on the second passivation layer, the pixel electrode being electrically connected to the drain electrode.

In an exemplary embodiment, the first passivation layer and the common electrode may be formed by the same mask.

In an exemplary embodiment, the first passivation layer, the common electrode and the second passivation layer may be formed by the same mask.

In an exemplary embodiment, the common electrode may form an under-cut structure with the second passivation layer.

In an exemplary embodiment, the gate metal pattern may further include a gate pad electrically connected to the gate line. The data metal pattern may further include a signal line contacted with the gate pad to apply a gate signal to the gate pad.

In an exemplary embodiment, the method may further include forming a first photoresist pattern on the etch-stop layer, the first photoresist pattern having through holes overlapping the gate pad, the first photoresist pattern comprising a first thickness portion and a second thickness portion thinner than the first thickness portion, etching the etch-stop layer and the gate insulation layer by using the first photoresist pattern as a mask to expose the gate pad, partially removing the first photoresist pattern to form a second photoresist pattern having through holes overlapping the active pattern and etching the etch-stop layer by using the second photoresist pattern as a mask to expose a portion of the active pattern.

In an exemplary embodiment, the etch-stop layer may include a silicon oxide or a silicon nitride.

In an exemplary embodiment, the data metal pattern may have a single-layered structure or a multiple-layered structure comprising titanium.

In an exemplary embodiment, the active pattern may include an oxide semiconductor.

In an exemplary embodiment, the first passivation layer may include an inorganic insulating material.

According to the present exemplary embodiment, an oxide semiconductor layer does not remain under a data line. Thus, problems due to an active protrusion may be prevented. In addition, the first passivation layer is not an organic layer but an inorganic insulating layer. Therefore, the number of mask required for forming the organic layer may be decreased.

In addition, an active pattern is exposed after a gate pad is exposed in the process of etching an etch-stop layer to expose the active pattern and the gate pad. Thus, damage to the active pattern may be prevented. Furthermore, the above processes may be performed without an additional mask by using half-tone light exposure.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings, in which like reference symbols indicate the same or similar components, wherein:

FIG. 1 is a plan view illustrating a thin film transistor substrate according to an exemplary embodiment of the inventive concept;

FIG. 2 is a plan view illustrating a thin film transistor substrate according to an exemplary embodiment of the inventive concept;

FIG. 3 is a cross-sectional view taken along the line I-I′ of FIG. 2;

FIGS. 4 to 13 are cross-sectional views illustrating a method of manufacturing the thin film transistor substrate of FIG. 3;

FIG. 14 is a plan view illustrating a thin film transistor substrate according to an exemplary embodiment of the inventive concept;

FIG. 15 is a cross-sectional view taken along the line II-IF of FIG. 14;

FIGS. 16 to 25 are cross-sectional views illustrating a method of manufacturing the thin film transistor substrate of FIG. 15;

FIG. 26 is a plan view illustrating a thin film transistor substrate according to an exemplary embodiment of the inventive concept;

FIG. 27 is a cross-sectional view taken along the line III-III′ of FIG. 26; and

FIGS. 28 to 36 are cross-sectional views illustrating a method of manufacturing the thin film transistor substrate of FIG. 27.

### DETAILED DESCRIPTION OF THE INVENTION

Hereinafter, the present invention will be explained in detail with reference to the accompanying drawings.

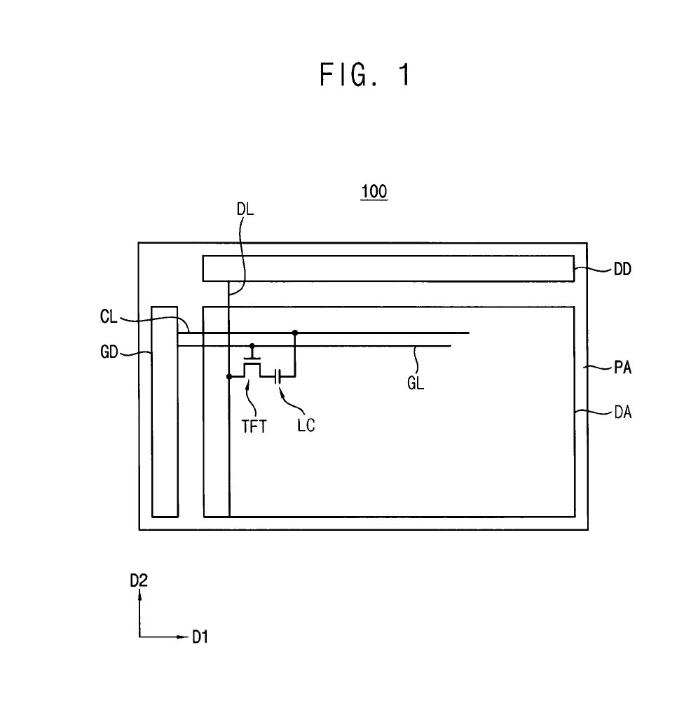

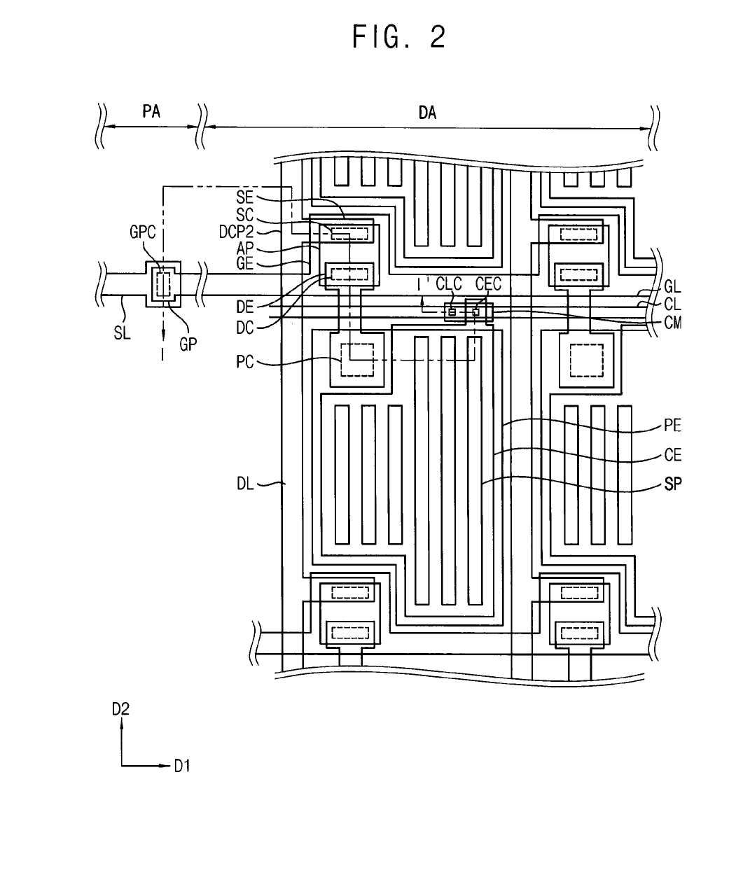

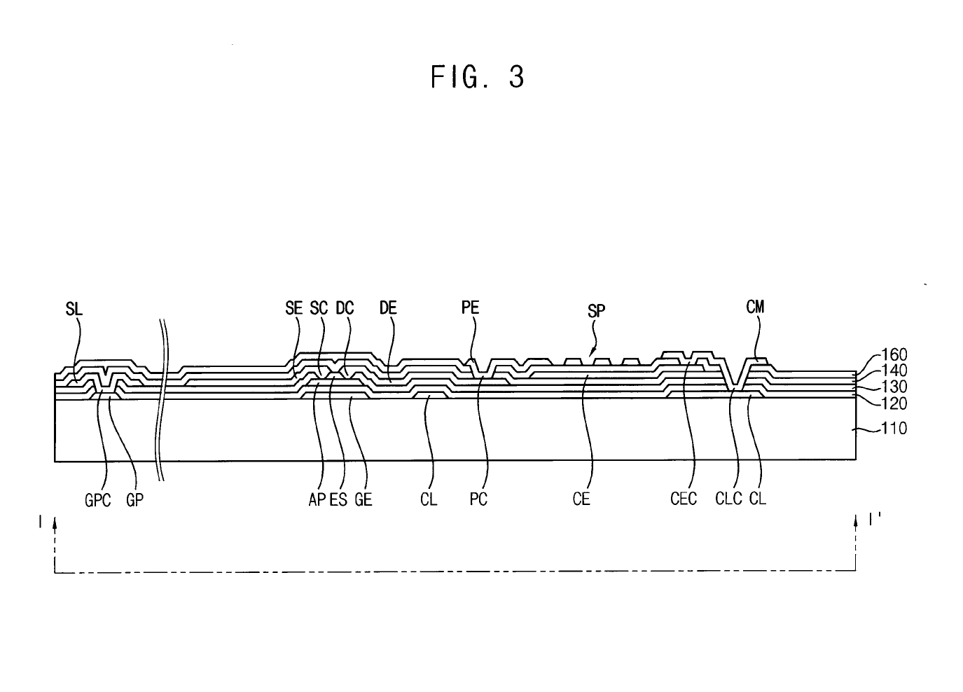

FIG. 1 is a plan view illustrating a thin film transistor substrate according to an exemplary embodiment of the inventive concept. FIG. 2 is a plan view illustrating a thin film transistor substrate according to an exemplary embodiment of the inventive concept. FIG. 3 is a cross-sectional view taken along the line I-I′ of FIG. 2.

Referring to FIGS. 1 to 3, a thin film transistor substrate may be a display substrate of a liquid crystal display panel for a liquid crystal display device. For example, the liquid crystal display panel may include the display substrate, an opposing substrate facing the display substrate and a liquid crystal layer interposed between the display substrate and the opposing substrate.

The thin film transistor substrate may include a display area DA and a peripheral area PA surrounding the display area DA. An array of a thin film transistor TFT is disposed on in the display area DA.

The thin film transistor TFT is electrically connected to a gate line GL and a data line DL. A drain electrode of the thin film transistor TFT is electrically connected to a pixel electrode PE. The pixel electrode PE forms a liquid crystal capacitor LC with a common electrode CE electrically connected to a common line CL.

A gate driver GD providing a gate signal to the gate line GL and a data driver DD providing a data signal to the data line DL may be disposed on in the peripheral area PA. The gate driver GD and the data driver DD may be connected to an external control substrate (not shown) to receive a driving signal.

In the embodiment, the gate driver GD may include a thin film transistor integrated on a base substrate. Thus, the gate driver GD may be formed through the same process as the thin film transistor TFT of the display area DA. The data driver DD may be integrated on the base substrate, or may be mounted on a tape carrier package, a flexible printed circuit board or the like.

The thin film transistor TFT includes a gate electrode GE, an active pattern AP, a source electrode SE and a drain electrode DE.

The gate line GL extends in a first direction D1, and the data line DL extends in a second direction D2, in a plan view. The first direction D1 intersects with the second direction D2. Furthermore, the first direction D1 may be substantially perpendicular to the second direction D2.

The gate line GL is electrically connected to the gate electrode GE. For example, the gate electrode GE may protrude from the gate line GL in the second direction D2. In another embodiment, a portion of the gate line GL may overlap the active pattern AP to function as the gate electrode GE so that the gate electrode GE may not protrude from the gate line GL.

An end of the gate line GL is connected to a gate pad GP. The gate pad GP is disposed on in the peripheral area PA surrounding the display area DA. A gate signal is applied to the gate line GL through the gate pad GP. The gate pad GP contacts a signal line SL transmitting the gate signal. The signal line SL may be electrically connected to a drain electrode of the thin film transistor of the gate driver GD.

The thin film transistor substrate further includes a common line CL electrically connected to the common electrode CE to provide a common voltage to the common electrode CE. The common line CL may be disposed on in the same layer as the gate line GL (FIG. 2).

The thin film transistor substrate further includes a gate insulation layer 120 that covers the gate electrode GE, the gate line GL and the common line CL.

The active pattern AP overlaps the gate electrode GE. The active pattern AP is disposed on the gate insulation layer 120. The active pattern AP includes an oxide semiconductor. When a gate voltage is applied to the gate electrode GE, the active pattern AP becomes a conductor to function as a channel.

The thin film transistor substrate further includes an etch-stop layer 130 covering the active pattern AP.

The source electrode SE and the drain electrode DE are spaced apart from each other, and contact the active pattern AP, respectively. The source electrode SE and the drain electrode DE are disposed on the etch-stop layer 130.

The etch-stop layer 130 has a first through hole SC and a second through hole DC. The source electrode SE contacts the active pattern AP through the first through hole SC. In addition, the drain electrode DE contacts the active pattern AP through the second through hole DC.

The signal line SL may be disposed on in the same layer as the source electrode SE (FIG. 3). The signal line SL contacts the gate pad GP through a contact hole formed through the gate insulation layer 120.

In an embodiment, the signal line SL of the gate driver GD is directly connected to the gate pad GP unlike a conventional thin film transistor substrate that uses a transparent conductive pattern as a bridge. Thus, a space for the bridge is not necessary. Thus, a bezel of a display panel including the thin film transistor substrate may be reduced. Furthermore, connection failure due to damage of the bridge or inflow of static electricity through the bridge may be prevented.

The thin film transistor substrate further includes a first passivation layer 140 covering the thin film transistor. The first passivation layer 140 may include an inorganic insulating material. The common electrode CE is disposed on the first passivation layer 140. The thin film transistor substrate further includes a second passivation layer 160 covering the common electrode CE. The pixel electrode PE is disposed on the second passivation layer 160.

In the embodiment, the pixel electrode PE is disposed on the common electrode CE. However, the pixel electrode PE may be disposed under the common electrode CE in another embodiment. Furthermore, the common electrode CE may be formed on an opposing substrate spaced apart from the thin film transistor substrate in another embodiment.

The pixel electrode PE is disposed on the second passivation layer 160. The pixel electrode PE has a slit portion SP. The slit portion SP may extend, for example, in the second direction D2, and may includes a plurality of slits arranged in the first direction D1. The pixel electrode PE overlaps the common electrode CE to form an electric field depending on a voltage applied thereto so as to control an arrangement of liquid crystal molecules disposed thereon. The pixel electrode PE includes a pixel contact PC passing through the second passivation layer 160 and the first passivation layer 140 to contact the drain electrode DE.

The common electrode CE and the pixel electrode PE may include a transparent conductive material such as indium zinc oxide, indium tin oxide or the like.

The thin film transistor substrate further includes a connection member CM electrically connecting the common electrode CE to the common line CL. The connection member CM may be disposed in the same layer as the pixel electrode PE. The connection member CM includes a common electrode contact CEC and a common line contact CLC. The common electrode contact CEC passes through the second passivation layer 160 to contact the common electrode CE, and the common line contact CLC passes through the second passivation layer 160, the first passivation layer 140, the etch-stop layer 130 and the gate insulation layer 120 to contact the common line CL.

In another embodiment, the thin film transistor substrate may further include a color filter and/or a black matrix disposed on the passivation layer 140.

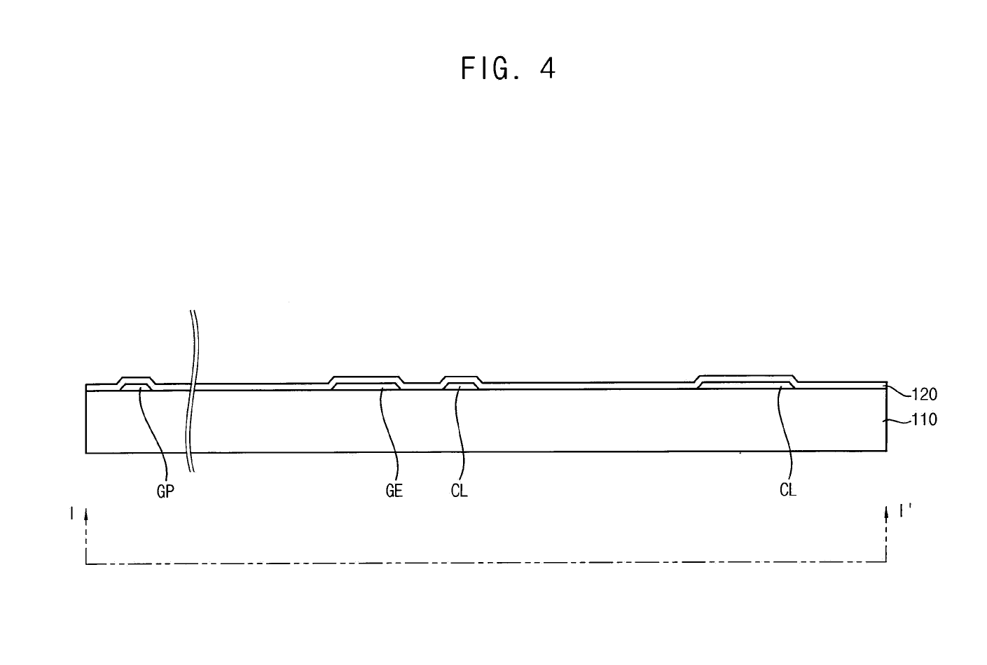

FIGS. 4 to 13 are cross-sectional views illustrating a method of manufacturing the thin film transistor substrate of FIG. 3.

Referring to FIG. 4, a gate metal layer is formed on a base substrate 110, and patterned to form a gate metal pattern including a gate electrode GE, a common line CL and a gate pad GP. The gate metal pattern further includes a gate line continuously connected to the gate electrode GE and the gate pad GP.

Examples of the base substrate 110 may include a glass substrate, a quartz substrate, a silicon substrate, a plastic substrate and the like.

Examples of a material that may be used for the gate metal layer may include copper, silver, chromium, molybdenum, aluminum, titanium, manganese, or an alloy thereof. The gate metal layer may have a single-layered structure or may have a multiple-layered structure including different materials. For example, the gate metal layer may include a copper layer and a titanium layer disposed on and/or under the copper layer.

In another embodiment, the gate metal layer may include a metal layer and a conductive oxide layer disposed on and/or under the metal layer. For example, the gate metal layer may include a copper layer and a conductive oxide layer disposed on and/or under the copper layer. Examples of a material that may be used for the conductive oxide layer may include indium zinc oxide, indium tin oxide, gallium zinc oxide, and zinc aluminum oxide.

Thereafter, a gate insulation layer 120 is formed to cover the gate metal pattern. Examples of a material that may be used for the gate insulation layer 120 may include silicon nitride, silicon oxide, aluminum oxide, hafnium oxide, titanium oxide and the like. The gate insulation layer 120 may have a single-layered structure or a multiple-layered structure. For example, the gate insulation layer 120 may include a lower insulation layer including silicon nitride and an upper insulation layer including silicon oxide.

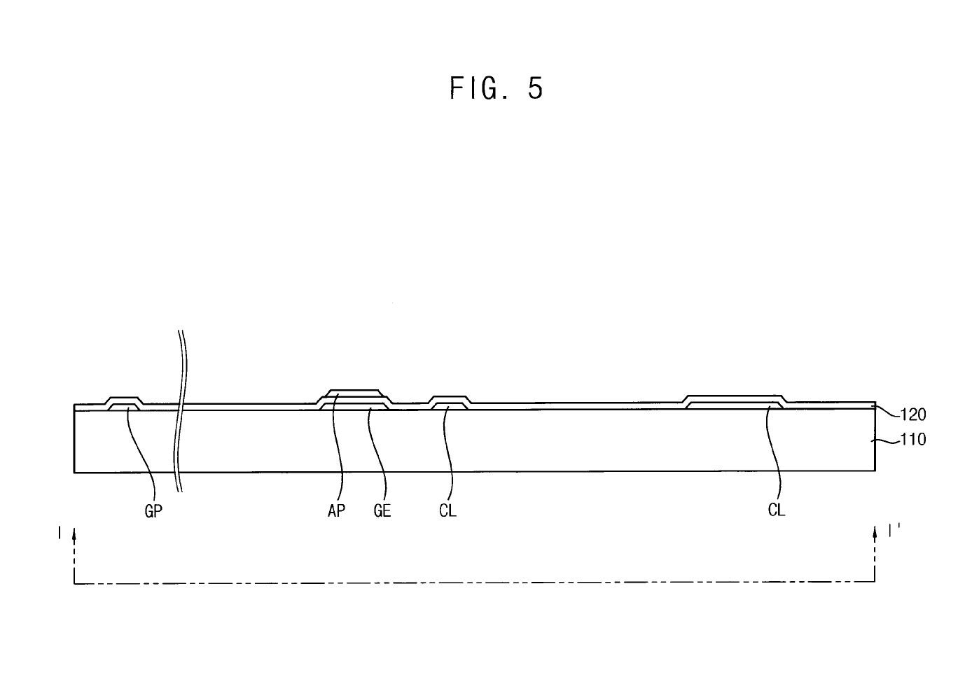

Referring to FIG. 5, an active layer is formed on the gate insulation layer 120 and patterned to form an active pattern AP. The active pattern AP includes an oxide semiconductor. Examples of the oxide semiconductor may include zinc oxide, zinc tin oxide, indium zinc oxide, indium oxide, titanium oxide, indium gallium zinc oxide, indium zinc tin oxide and the like. The active pattern AP overlaps the gate electrode GE.

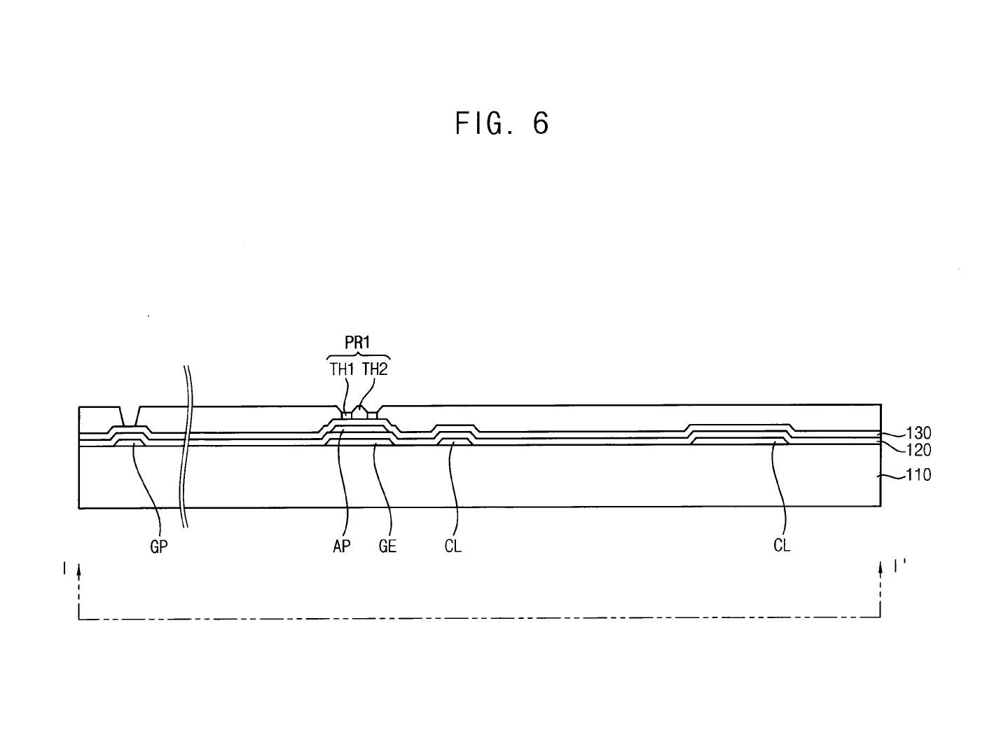

Referring to FIG. 6, an etch-stop layer 130 is formed to cover the active pattern AP. Examples of a material that may be used for the etch-stop layer 130 may include silicon nitride, silicon oxide, aluminum oxide, hafnium oxide, titanium oxide and the like.

A first photoresist pattern PR1 is formed on the etch-stop layer 130. The first photoresist pattern PR1 may be formed on substantially an entire portion of the etch-stop layer 130.

The first photoresist pattern PR1 has through holes exposing a portion of the etch-stop layer 130. For example, the through hole may overlap the gate pad GP.

The first photoresist pattern PR1 includes a first thickness portion TH1 and a second thickness portion TH2 thicker than the first thickness portion TH1. The first thickness portion TH1 overlaps the active pattern AP.

For example, a photoresist is coated, and exposed to a light through a half-tone exposure and developed by a developing solution to form the first photoresist pattern PR1.

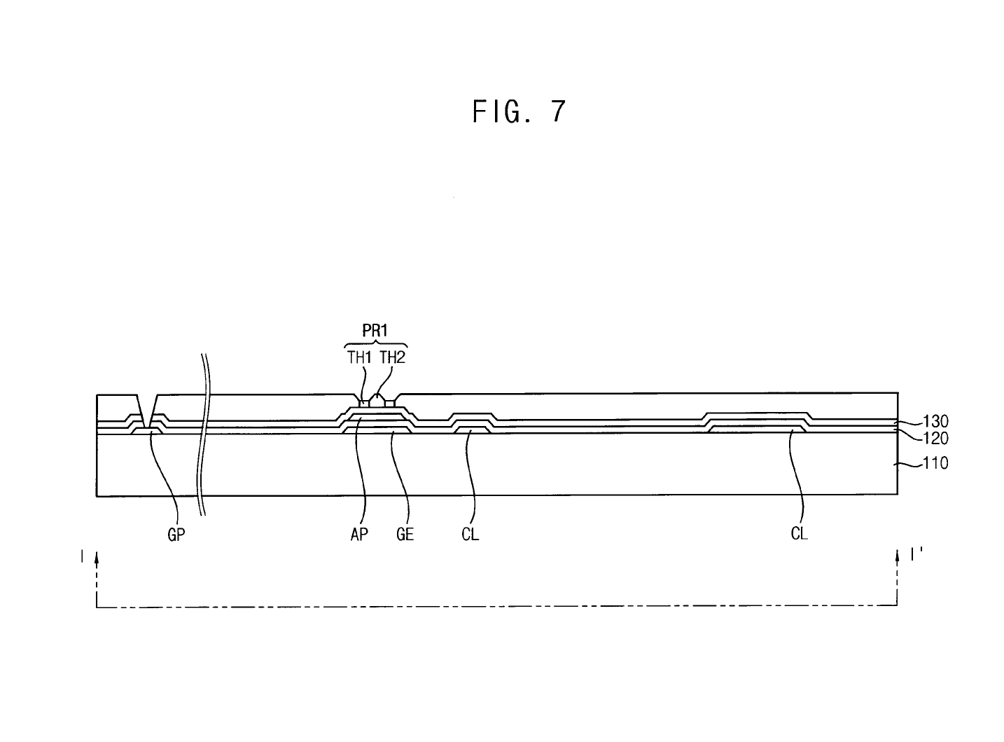

Referring to FIG. 7, the etch-stop layer 130 and the gate insulation layer 120 are etched by using the first photoresist pattern mask PR1 as a mask. Thus, the gate pad GP is exposed.

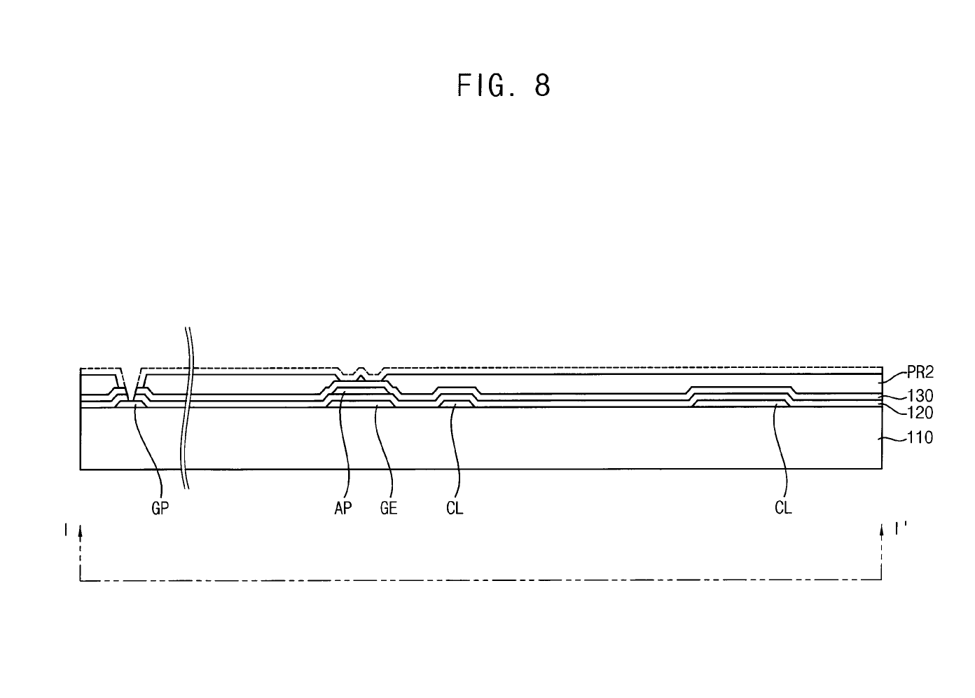

Referring to FIG. 8, the first photoresist pattern PR1 is partially removed, for example, through an ashing process. As a result, the first thickness portion TH1 is removed, and the second thickness portion TH2 partially remains to form a second photoresist pattern PR2.

The second photoresist pattern PR2 has a through hole exposing the etch-stop layer 130 overlapping the active pattern AP. Furthermore, through the ashing process, an upper surface of the etch-stop layer 130 adjacent to the gate pad GP may be exposed.

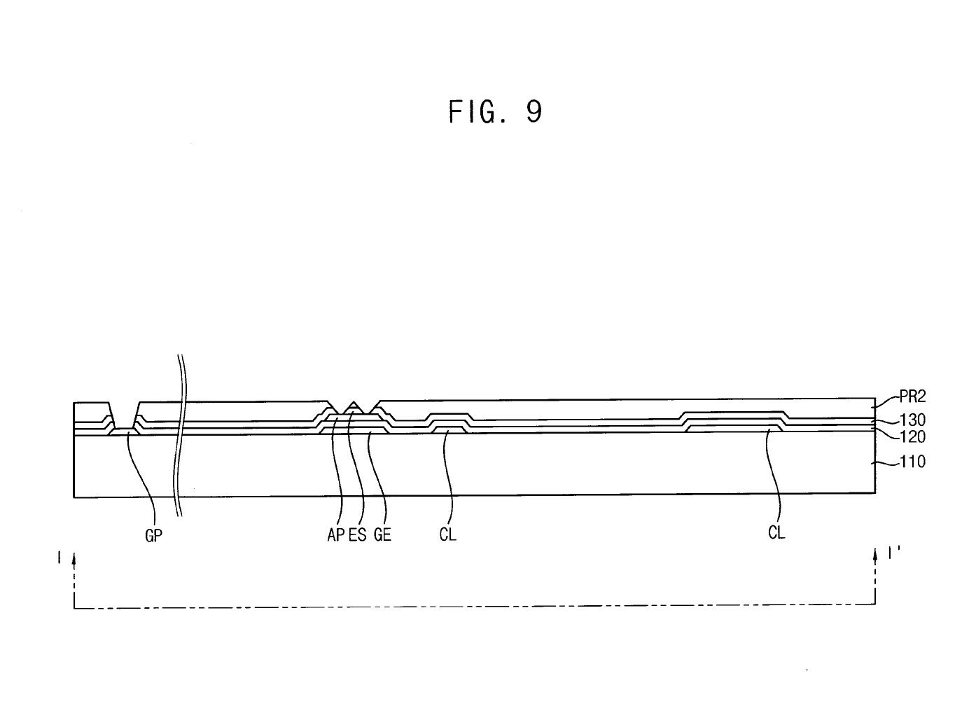

Referring to FIG. 9, the etch-stop layer 130 is etched by using the second photoresist pattern PR2 as a mask to form a first through hole SC and a second through hole DC exposing the active pattern AP.

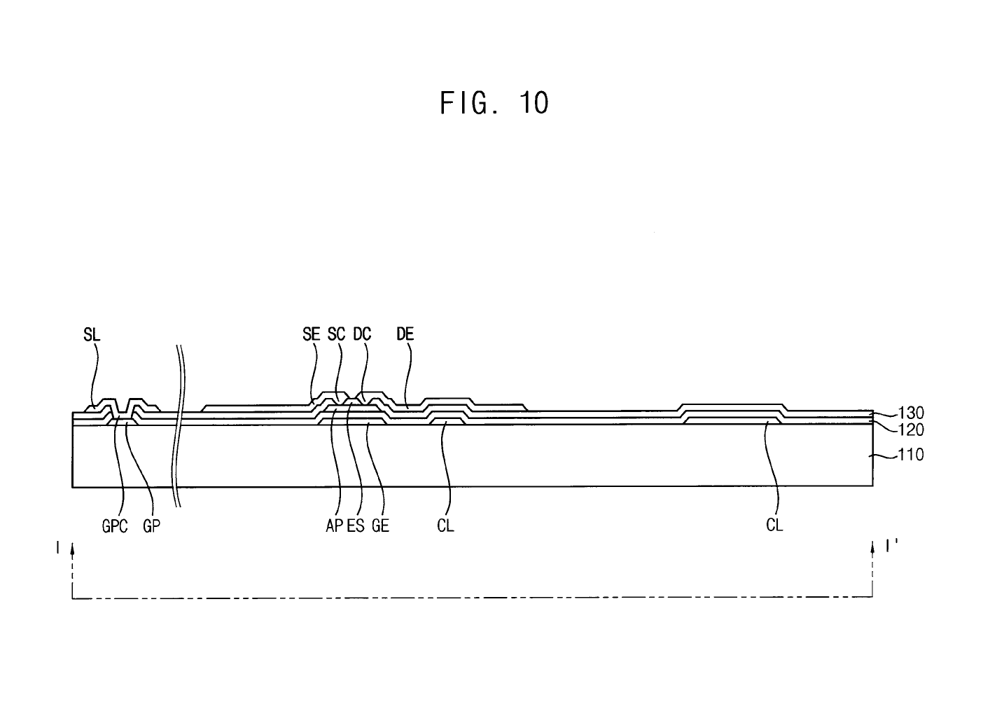

Referring to FIG. 10, a data metal layer is formed on the etch-stop layer 130 after the second photoresist pattern PR2 is removed.

In an embodiment, the data metal layer may include titanium. Particularly, the data metal layer may have a titanium single-layered structure or a multiple-layered structure further including a different metal layer. For example, the data metal layer may have a double-layered structure of a lower titanium layer and an upper copper layer, or a triple-layered structure of titanium/aluminum/titanium.

In another embodiment, the data metal layer may have a single-layered structure of a transparent conductive oxide. According to a conventional method, a data line does not include a transparent conductive oxide as a main layer because of low conductivity. In the embodiment, a source electrode, a drain electrode and a portion of a data line may be formed from a transparent conductive oxide. The data metal layer including a transparent conductive oxide may be etched by the same etchant as a pixel electrode.

Thus, etchants required for manufacturing a thin film transistor substrate may be reduced if the data metal layer includes a transparent conductive oxide.

The data metal layer is patterned to form a data metal pattern including a source electrode SE, a drain electrode DE and a signal line SL.

The source electrode SE contacts with the active pattern AP through the first through hole SC. The drain electrode DE contacts with the active pattern AP through the second through hole DC.

As illustrated in FIG. 1, the thin film transistor substrate according to an exemplary embodiment includes a thin film transistor constituting the gate driver GD, and the thin film transistor may be formed through the same process as the thin film transistor in the display area DA. Thus, the signal line SL may be a portion of a drain electrode of the thin film transistor in the gate driver GD, or may be connected to the drain electrode of thin film transistor in the gate driver GD.

In the embodiment, the signal line SL includes a gate pad contact GPC passing through the gate insulation layer 120 and the etch-stop layer 130 to contact the gate pad GP. Thus, a width of a bezel of a display panel may be reduced. Furthermore, reliability deterioration due to using a bridge may be prevented.

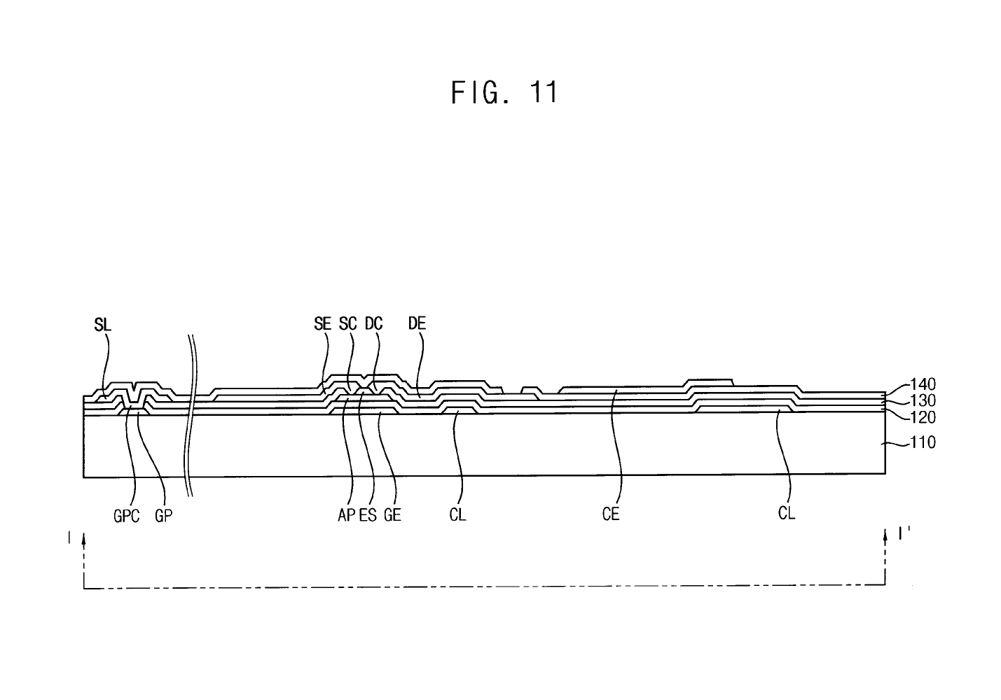

Referring to FIG. 11, a first passivation layer 140 and a common electrode CE are formed on the base substrate on which the data metal pattern is formed.

The first passivation layer 140 may include an inorganic insulation material such as silicon oxide, silicon nitride or the like. The common electrode CE is formed on the first passivation layer 140. The first passivation layer 140 and the common electrode CE are formed by the same mask. The common electrode CE may be formed by wet-etching process. The first passivation layer 140 may be formed by dry-etching process.

According to the present exemplary embodiment, the first passivation layer 140 is not an organic layer but an inorganic insulating layer. In addition, the first passivation layer 140 and the common electrode CE are formed by the same mask. Therefore, the number of mask required for manufacturing process may be decreased.

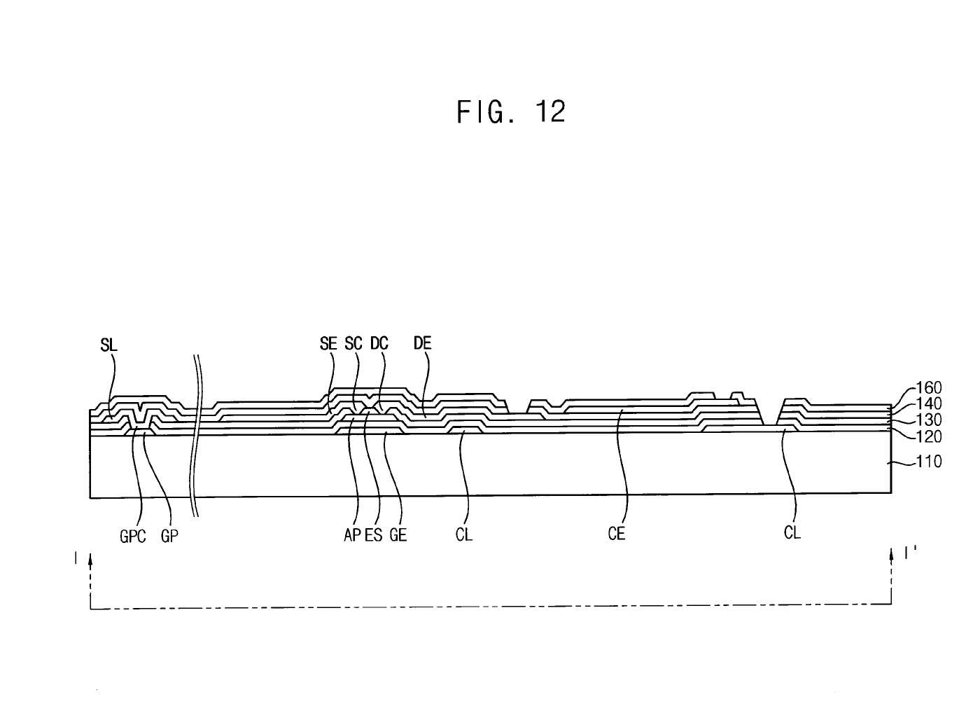

Referring to FIG. 12, a second passivation layer 160 is formed on the base substrate on which the common electrode CE.

The second passivation layer 160 covers the first passivation layer 140 and the common electrode CE. The second passivation layer 160 may include an inorganic insulation material such as silicon oxide, silicon nitride or the like.

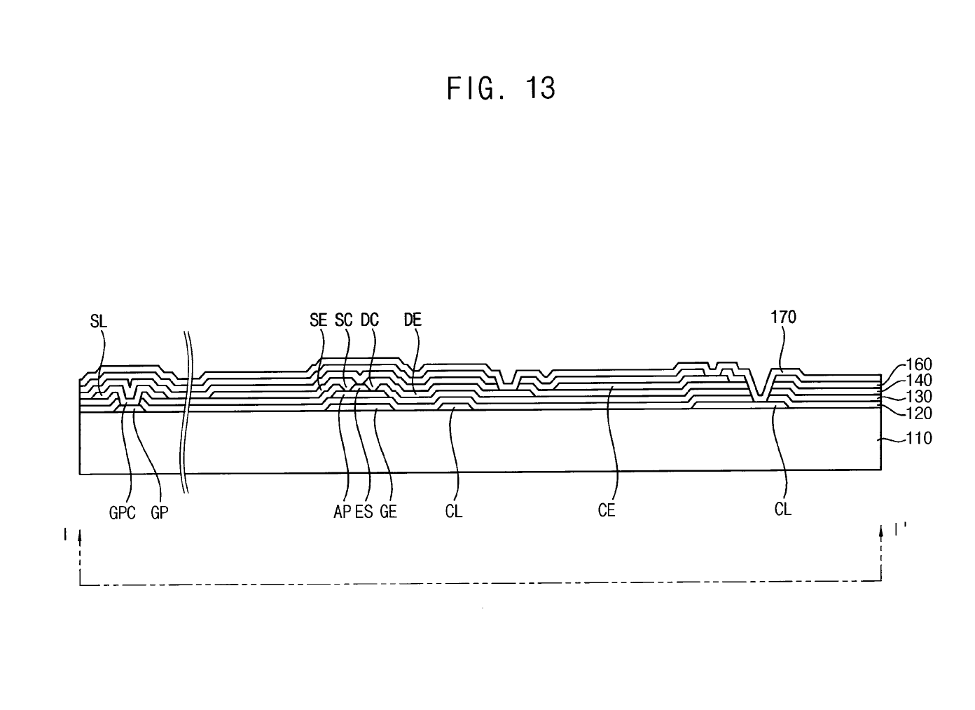

Referring to FIG. 13, a transparent conductive layer 170 is formed on the base substrate on which the second passivation layer 160 is formed.

The transparent conductive layer 170 may include a transparent conductive material, such as indium tin oxide (ITO), indium zinc oxide (IZO) and etc. In addition, the transparent conductive layer 170 may include titanium (Ti) and/or molybdenum titanium (MoTi).

Referring to FIG. 3, the transparent conductive layer 170 is patterned to form a pixel electrode PE and a connection member CM. The pixel electrode PE contacts the drain electrode DE and overlaps the common electrode CE. The pixel electrode PE has an opening forming a slit portion SP extending in a direction. The connection member CM contacts the common electrode CE and the common line CL so that the common electrode CE and the common line CL are electrically connected to each other.

The pixel electrode PE and the connection member CM may include a transparent conductive material, such as indium tin oxide (ITO), indium zinc oxide (IZO) and etc. In addition, the pixel electrode PE and the connection member CM may include titanium (Ti) and/or molybdenum titanium (MoTi).

According to the embodiment, an oxide semiconductor layer does not remain under a data line. Thus, problems due to an active protrusion may be prevented.

Furthermore, an active pattern is exposed after a gate pad is exposed in the process of etching an etch-stop layer to expose the active pattern and the gate pad. Thus, damage to the active pattern may be prevented. Furthermore, the above processes may be performed without an additional mask by using half-tone light exposure.

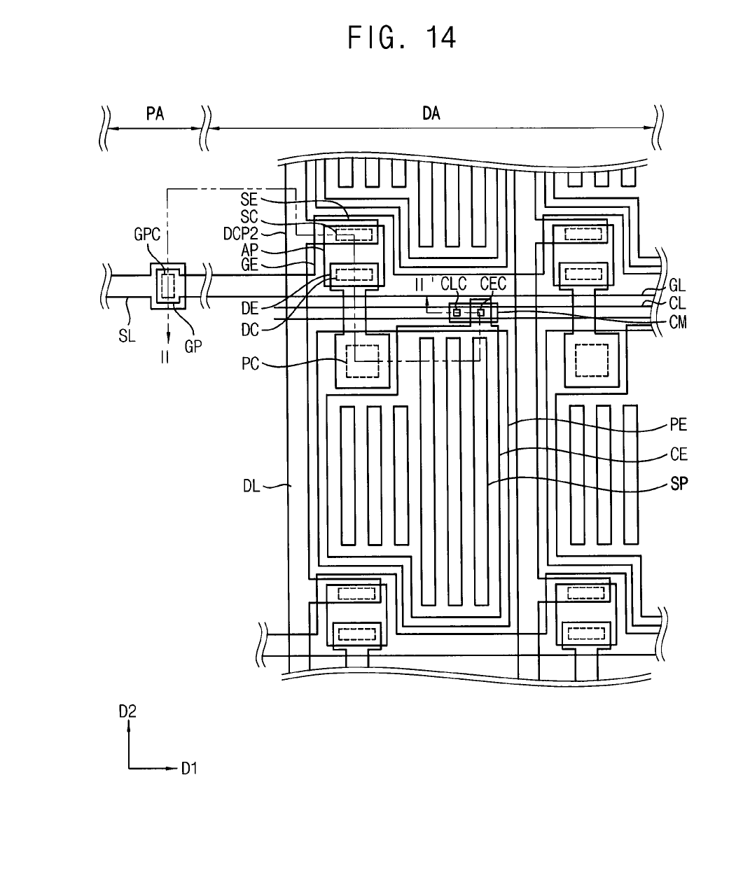

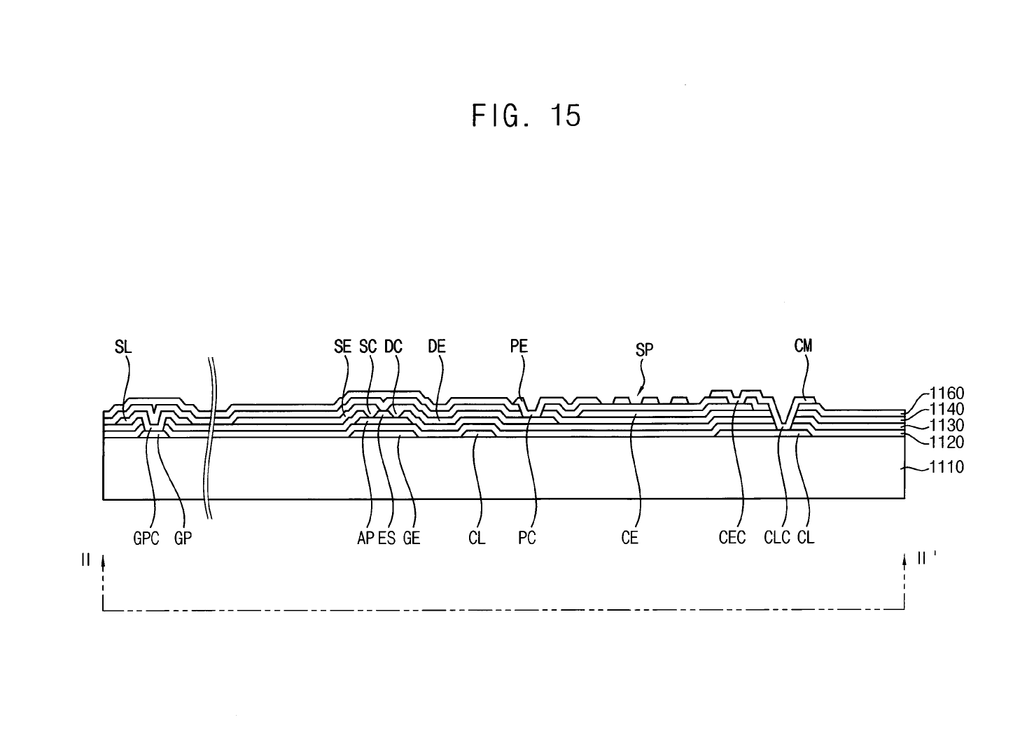

FIG. 14 is a plan view illustrating a thin film transistor substrate according to an exemplary embodiment of the inventive concept. FIG. 15 is a cross-sectional view taken along the line II-IF of FIG. 14.

Referring to FIGS. 1, 14 and 15, a thin film transistor substrate may be a display substrate of a liquid crystal display panel for a liquid crystal display device. For example, the liquid crystal display panel may include the display substrate, an opposing substrate facing the display substrate and a liquid crystal layer interposed between the display substrate and the opposing substrate.

The thin film transistor substrate may include a display area DA and a peripheral area PA surrounding the display area DA. An array of a thin film transistor TFT is disposed in the display area DA.

The thin film transistor TFT is electrically connected to a gate line GL and a data line DL. A drain electrode of the thin film transistor TFT is electrically connected to a pixel electrode PE. The pixel electrode PE forms a liquid crystal capacitor LC with a common electrode CE electrically connected to a common line CL.

A gate driver GD providing a gate signal to the gate line GL and a data driver DD providing a data line to the data line DL may be disposed in the peripheral area PA. The gate driver GD and the data driver DD may be connected to an external control substrate to receive a driving signal.

In the embodiment, the gate driver GD may include a thin film transistor integrated on a base substrate. Thus, the gate driver GD may be formed through the same process as the thin film transistor TFT of the display area DA. The data driver DD may be integrated on the base substrate, or may be mounted on a tape carrier package, a flexible printed circuit board or the like.

The thin film transistor TFT includes a gate electrode GE, an active pattern AP, a source electrode SE and a drain electrode DE.

The gate line GL extends in a first direction D1, and the data line DL extends in a second direction D2, in a plan view. The first direction D1 intersects with the second direction D2. Furthermore, the first direction D1 may be substantially perpendicular to the second direction D2.

The gate line GL is electrically connected to the gate electrode GE. For example, the gate electrode GE may protrude from the gate line GL in the second direction D2. In another embodiment, a portion of the gate line GL may overlap the active pattern AP to function as the gate electrode GE so that the gate electrode GE may not protrude from the gate line GL.

An end of the gate line GL is connected to a gate pad GP. The gate pad GP is disposed in the peripheral area surrounding the display area DA. A gate signal is applied to the gate line GL through the gate pad GP. The gate pad GP contacts a signal line SL transmitting the gate signal. The signal line SL may be electrically connected to a drain electrode of the thin film transistor of the gate driver GD.

The thin film transistor substrate further includes a common line CL electrically connected to the common electrode CE to provide a common voltage to the common electrode CE. The common line CL may be disposed in the same layer as the gate line GL.

The thin film transistor substrate further includes a gate insulation layer 1120 that covers the gate electrode GE, the gate line GL and the common line CL.

The active pattern AP overlaps the gate electrode GE. The active pattern AP is disposed on the gate insulation layer 1120. The active pattern AP includes an oxide semiconductor. When a gate voltage is applied to the gate electrode GE, the active pattern AP becomes a conductor to function as a channel.

The thin film transistor substrate further includes an etch-stop layer 1130 covering the active pattern AP.

The source electrode SE and the drain electrode DE are spaced apart from each other, and contact the active pattern AP, respectively. The source electrode SE and the drain electrode DE are disposed on the etch-stop layer 1130.

The etch-stop layer 1130 has a first through hole SC and a second through hole DC. The source electrode SE contacts the active pattern AP through the first through hole SC. In addition, the drain electrode DE contacts the active pattern AP through the second through hole DC.

The signal line SL may be disposed in the same layer as the source electrode SE. The signal line SL contacts the gate pad GP through a contact hole formed through the gate insulation layer 1120.

In an embodiment, the signal line SL of the gate driver GD is directly connected to the gate pad GP unlike a conventional thin film transistor substrate that uses a transparent conductive pattern as a bridge. Thus, a space for the bridge is not necessary. Thus, a bezel of a display panel including the thin film transistor substrate may be reduced. Furthermore, connection failure due to damage of the bridge or inflow of static electricity through the bridge may be prevented.

The thin film transistor substrate further includes a first passivation layer 1140 covering the thin film transistor. The first passivation layer 1140 may include an inorganic insulating material. The common electrode CE is disposed on the first passivation layer 1140. The thin film transistor substrate further includes a second passivation layer 1160 covering the common electrode CE. The pixel electrode PE is disposed on the second passivation layer 1160.

In the embodiment, the pixel electrode PE is disposed on the common electrode CE. However, the pixel electrode PE may be disposed under the common electrode CE in another embodiment. Furthermore, the common electrode CE may be formed on an opposing substrate spaced apart from the thin film transistor substrate in another embodiment.

The pixel electrode PE is disposed on the second passivation layer 1160. The pixel electrode PE has a slit portion SP. The slit portion SP may extend, for example, in the second direction D2, and may includes a plurality of slits arranged in the first direction D1. The pixel electrode PE overlaps the common electrode CE to form an electric field depending on a voltage applied thereto so as to control an arrangement of liquid crystal molecules disposed thereon. The pixel electrode PE includes a pixel contact PC passing through the second passivation layer 1160 and the first passivation layer 1140 to contact the drain electrode DE.

The common electrode CE and the pixel electrode PE may include a transparent conductive material such as indium zinc oxide, indium tin oxide or the like.

The thin film transistor substrate further includes a connection member CM electrically connecting the common electrode CE to the common line CL. The connection member CM may be disposed in the same layer as the pixel electrode PE. The connection member CM includes a common electrode contact CEC and a common line contact CLC. The common electrode contact CEC passes through the second passivation layer 1160 to contact the common electrode CE, and the common line contact CLC passes through the second passivation layer 1160, the first passivation layer 1140, the etch-stop layer 1130 and the gate insulation layer 1120 to contact the common line CL.

In another embodiment, the thin film transistor substrate may further include a color filter and/or a black matrix disposed on the passivation layer 1140.

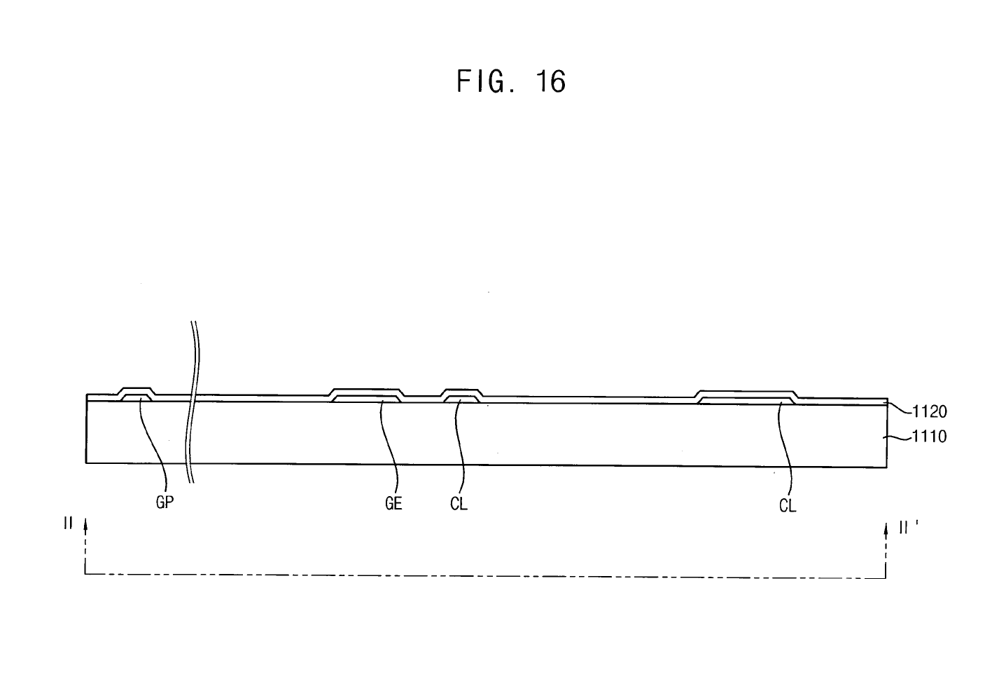

FIGS. 16 to 25 are cross-sectional views illustrating a method of manufacturing the thin film transistor substrate of FIG. 15.

Referring to FIG. 16, a gate metal layer is formed on a base substrate 1110, and patterned to form a gate metal pattern including a gate electrode GE, a common line CL and a gate pad GP. The gate metal pattern further includes a gate line continuously connected to the gate electrode GE and the gate pad GP.

Examples of the base substrate 1110 may include a glass substrate, a quartz substrate, a silicon substrate, a plastic substrate and the like.

Examples of a material that may be used for the gate metal layer may include copper, silver, chromium, molybdenum, aluminum, titanium, manganese, or an alloy thereof. The gate metal layer may have a single-layered structure or may have a multiple-layered structure including different materials. For example, the gate metal layer may include a copper layer and a titanium layer disposed on and/or under the copper layer.

In another embodiment, the gate metal layer may include a metal layer and a conductive oxide layer disposed on and/or under the metal layer. For example, the gate metal layer may include a copper layer and a conductive oxide layer disposed on and/or under the copper layer. Examples of a material that may be used for the conductive oxide layer may include indium zinc oxide, indium tin oxide, gallium zinc oxide, and zinc aluminum oxide.

Thereafter, a gate insulation layer 1120 is formed to cover the gate metal pattern. Examples of a material that may be used for the gate insulation layer 1120 may include silicon nitride, silicon oxide, aluminum oxide, hafnium oxide, titanium oxide and the like. The gate insulation layer 1120 may have a single-layered structure or a multiple-layered structure. For example, the gate insulation layer 1120 may include a lower insulation layer including silicon nitride and an upper insulation layer including silicon oxide.

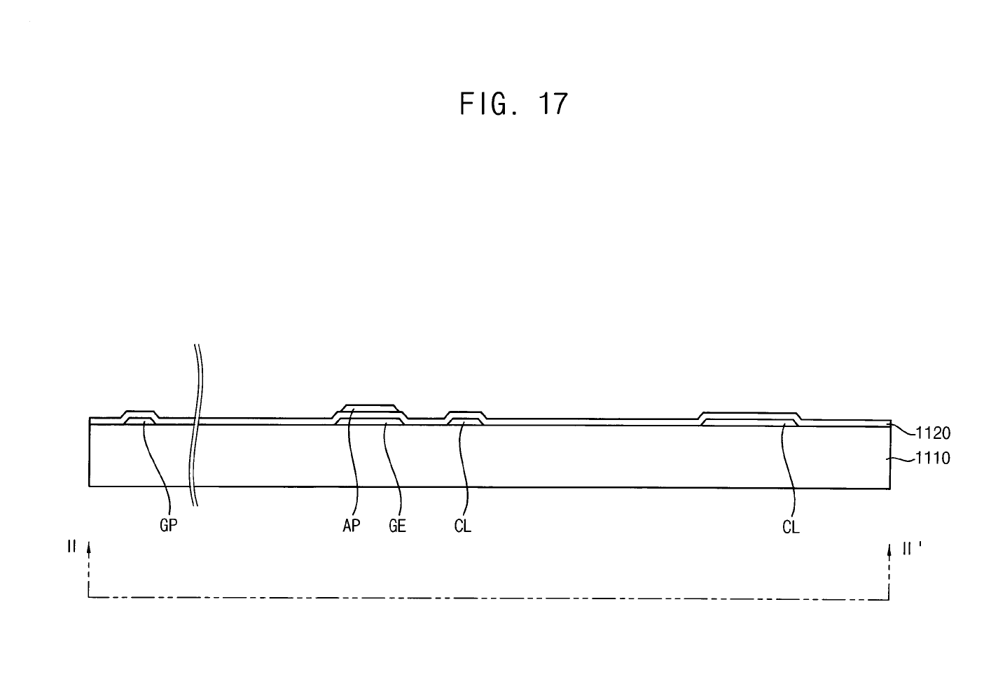

Referring to FIG. 17, an active layer is formed on the gate insulation layer 1120 and patterned to form an active pattern AP. The active pattern AP includes an oxide semiconductor. Examples of the oxide semiconductor may include zinc oxide, zinc tin oxide, indium zinc oxide, indium oxide, titanium oxide, indium gallium zinc oxide, indium zinc tin oxide and the like. The active pattern AP overlaps the gate electrode GE.

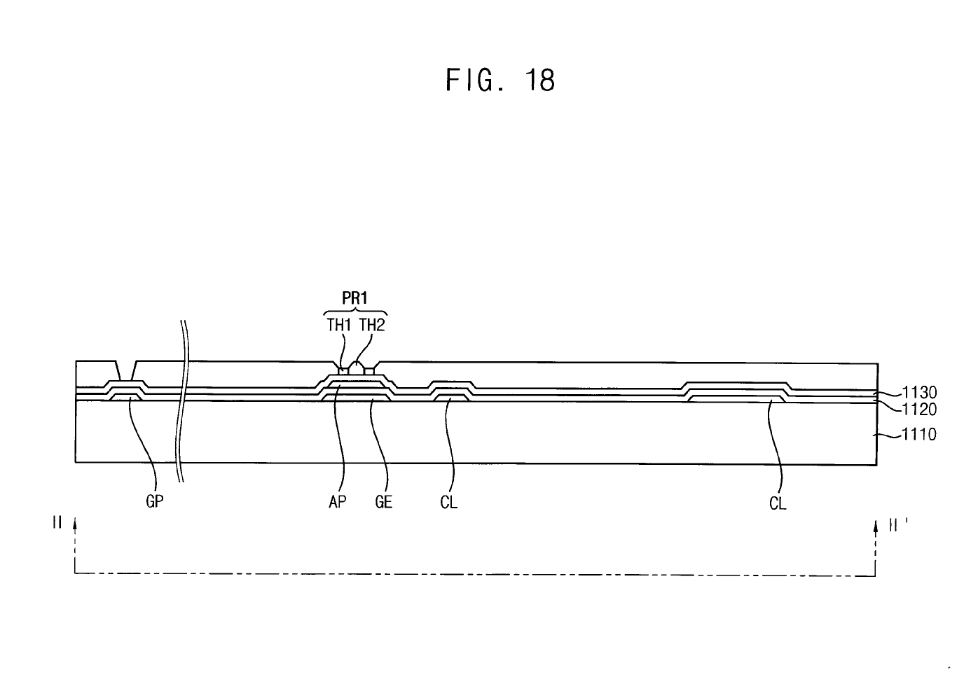

Referring to FIG. 18, an etch-stop layer 1130 is formed to cover the active pattern AP. Examples of a material that may be used for the etch-stop layer 1130 may include silicon nitride, silicon oxide, aluminum oxide, hafnium oxide, titanium oxide and the like.

A first photoresist pattern PR1 is formed on the etch-stop layer 1130. The first photoresist pattern PR1 may be formed on substantially an entire portion of the etch-stop layer 1130.

The first photoresist pattern PR1 has through holes exposing a portion of the etch-stop layer 1130. For example, the through hole may overlap the gate pad GP.

The first photoresist pattern PR1 includes a first thickness portion TH1 and a second thickness portion TH2 thicker than the first thickness portion TH1. The first thickness portion TH1 overlaps the active pattern AP.

For example, a photoresist is coated, and exposed to a light through a half-tone exposure and developed by a developing solution to form the first photoresist pattern PR1.

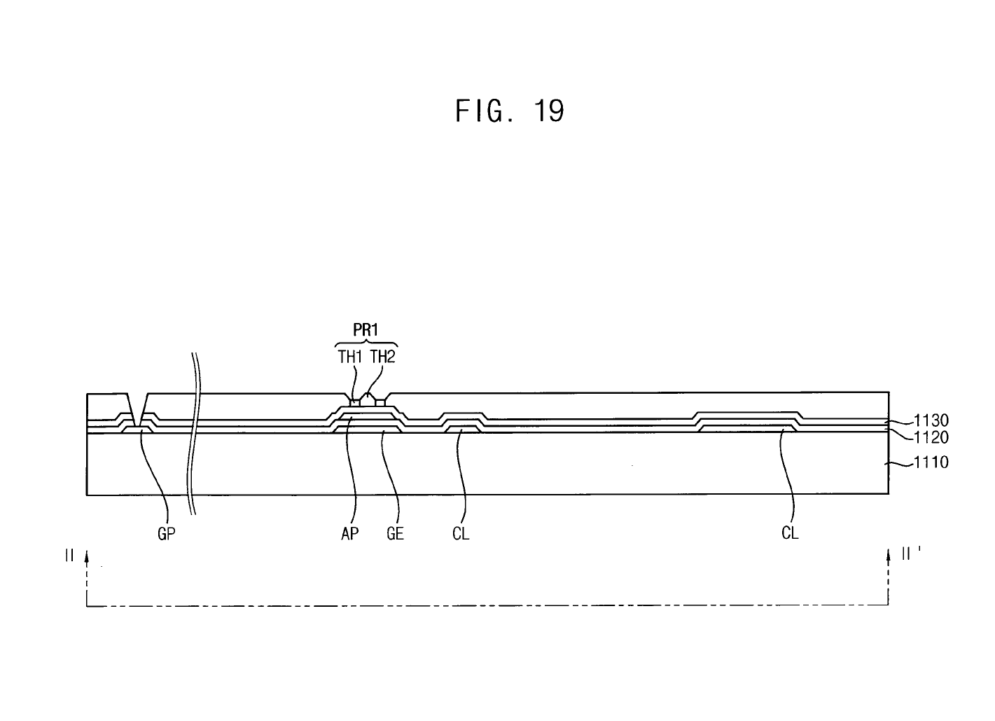

Referring to FIG. 19, the etch-stop layer 1130 and the gate insulation layer 1120 are etched by using the first photoresist pattern mask PR1 as a mask. Thus, the gate pad GP is exposed.

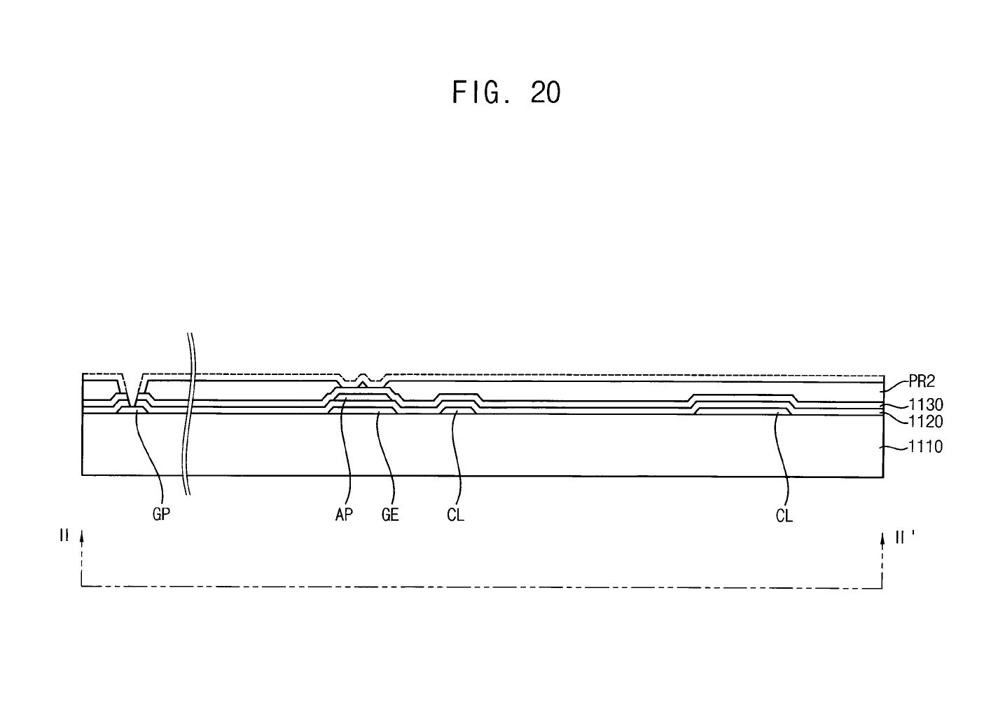

Referring to FIG. 20, the first photoresist pattern PR1 is partially removed, for example, through an ashing process. As a result, the first thickness portion TH1 is removed, and the second thickness portion TH2 partially remains to form a second photoresist pattern PR2.

The second photoresist pattern PR2 has a through hole exposing the etch-stop layer 1130 overlapping the active pattern AP. Furthermore, through the ashing process, an upper surface of the etch-stop layer 1130 adjacent to the gate pad GP may be exposed.

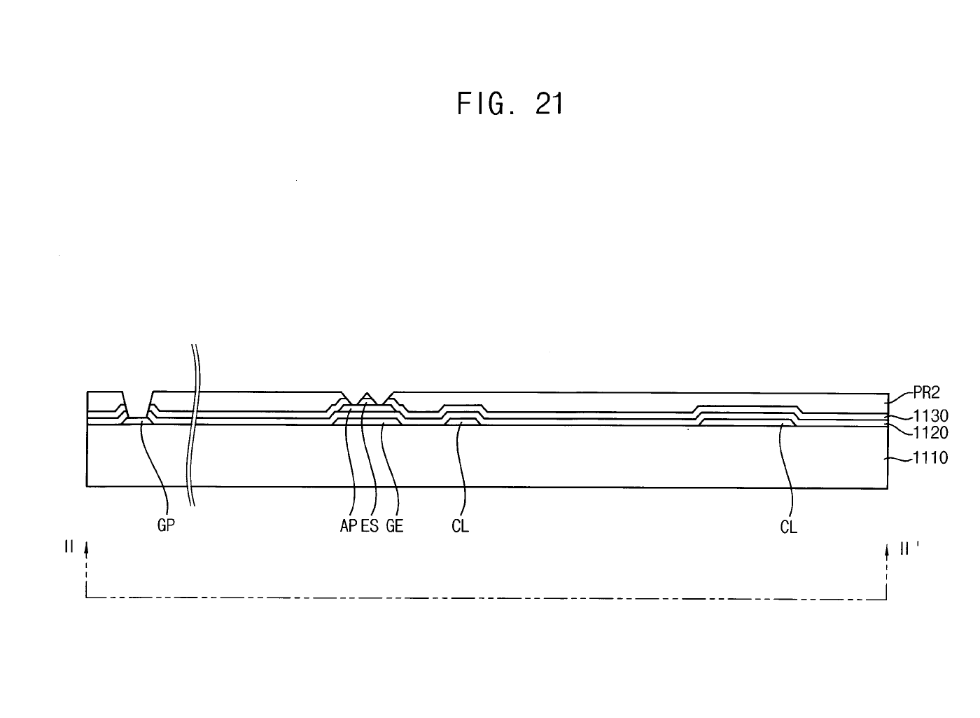

Referring to FIG. 21, the etch-stop layer 1130 is etched by using the second photoresist pattern PR2 as a mask to form a first through hole SC and a second through hole DC exposing the active pattern AP.

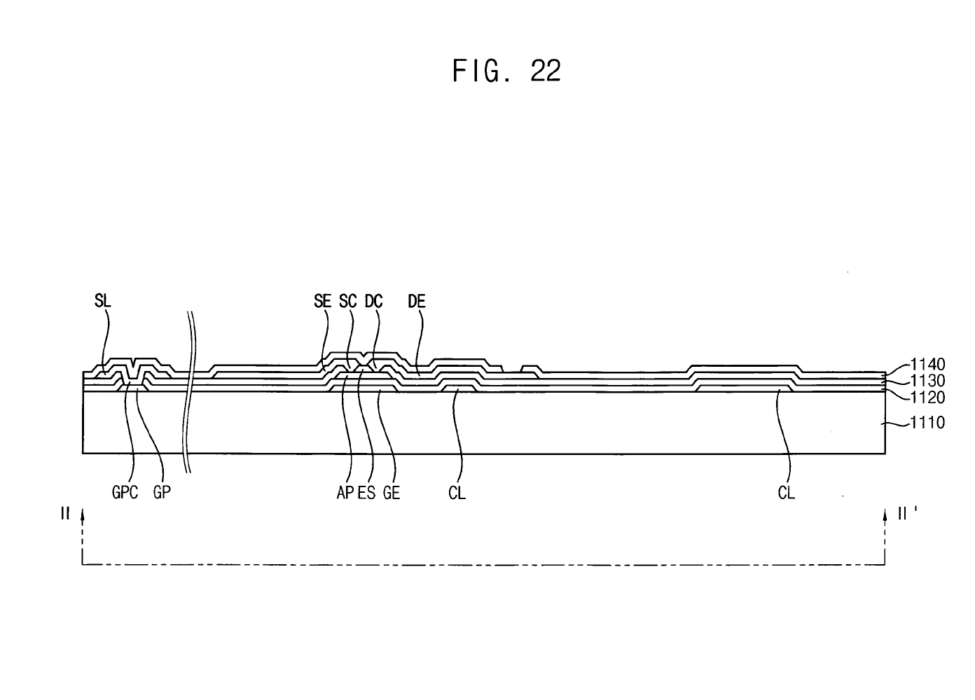

Referring to FIG. 22, a data metal layer is formed on the etch-stop layer 1130 after the second photoresist pattern PR2 is removed. Thereafter, a first passivation layer 1140 is formed.

In an embodiment, the data metal layer may include titanium. Particularly, the data metal layer may have a titanium single-layered structure or a multiple-layered structure further including a different metal layer. For example, the data metal layer may have a double-layered structure of a lower titanium layer and an upper copper layer, or a triple-layered structure of titanium/aluminum/titanium.

In another embodiment, the data metal layer may have a single-layered structure of a transparent conductive oxide. According to a conventional method, a data line does not include a transparent conductive oxide as a main layer because of low conductivity. In the embodiment, a source electrode, a drain electrode and a portion of a data line may be formed from a transparent conductive oxide. The data metal layer including a transparent conductive oxide may be etched by the same etchant as a pixel electrode.

Thus, etchants required for manufacturing a thin film transistor substrate may be reduced if the data metal layer includes a transparent conductive oxide.

The data metal layer is patterned to form a data metal pattern including a source electrode SE, a drain electrode DE and a signal line SL.

The source electrode SE contacts with the active pattern AP through the first through hole SC. The drain electrode DE contacts with the active pattern AP through the second through hole DC.

After the data metal layer is formed, the first passivation layer 1140 is formed. The first passivation layer 1140 includes an inorganic insulating material.

As illustrated in FIG. 1, the thin film transistor substrate according to an exemplary embodiment includes a thin film transistor constituting the gate driver GD, and the thin film transistor may be formed through the same process as the thin film transistor in the display area DA. Thus, the signal line SL may be a portion of a drain electrode of the thin film transistor in the gate driver GD, or may be connected to the drain electrode of thin film transistor in the gate driver GD.

In the embodiment, the signal line SL includes a gate pad contact GPC passing through the gate insulation layer 1120 and the etch-stop layer 1130 to contact the gate pad GP. Thus, a width of a bezel of a display panel may be reduced. Furthermore, reliability deterioration due to using a bridge may be prevented.

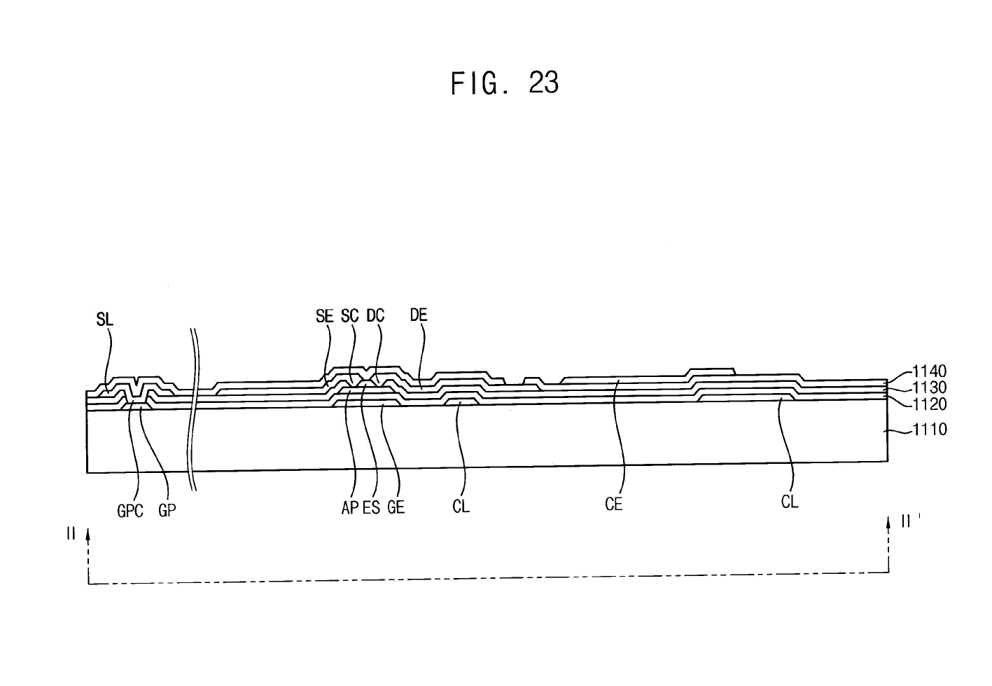

Referring to FIG. 23, a common electrode CE is formed on the base substrate on which the first passivation layer 1140 is formed.

The common electrode CE is disposed on the first passivation layer 1140. The common electrode CE may include a transparent conductive material, such as indium tin oxide (ITO), indium zinc oxide (IZO) and etc. In addition, the common electrode CE may include titanium (Ti) and/or molybdenum titanium (MoTi).

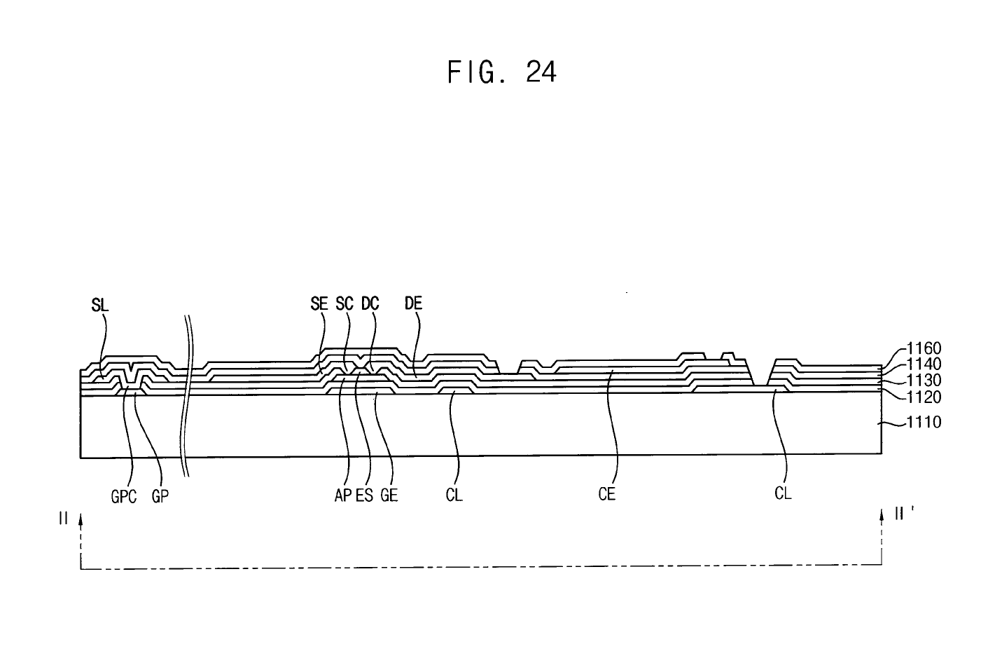

Referring to FIG. 24, a second passivation layer 1160 is formed on the base substrate on which the common electrode CE.

The second passivation layer 1160 covers the first passivation layer 1140 and the common electrode CE. The second passivation layer 1160 may include an inorganic insulation material such as silicon oxide, silicon nitride or the like.

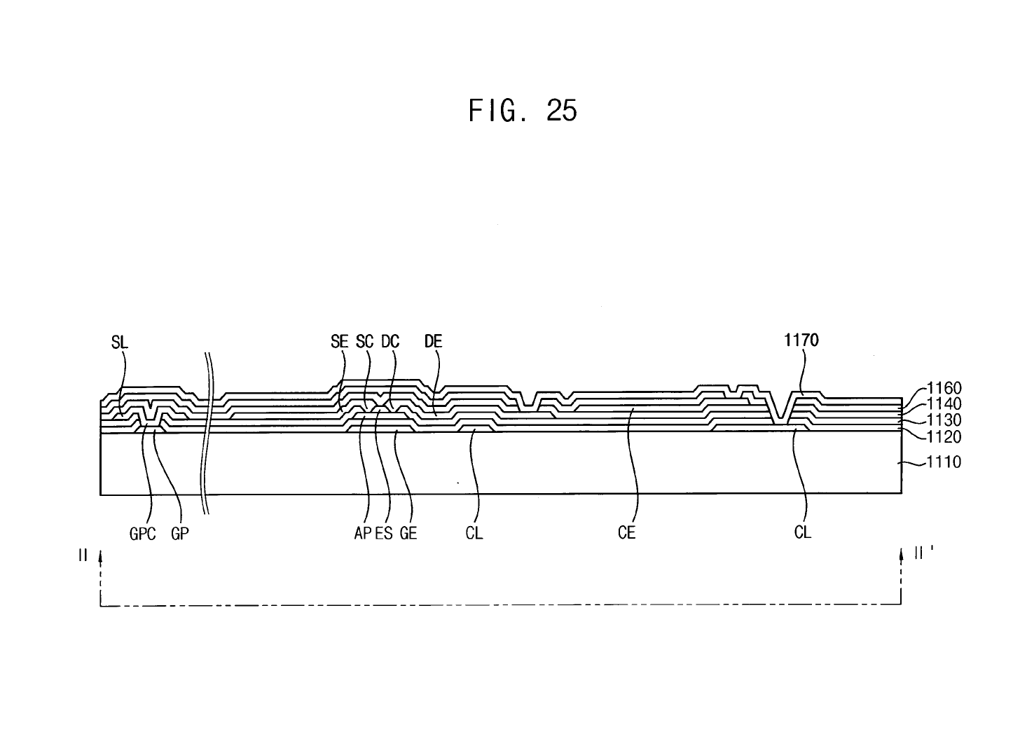

Referring to FIG. 25, a transparent conductive layer 1170 is formed on the base substrate on which the second passivation layer 1160 is formed.

The transparent conductive layer 1170 may include a transparent conductive material, such as indium tin oxide (ITO), indium zinc oxide (IZO) and etc. In addition, the transparent conductive layer 1170 may include titanium (Ti) and/or molybdenum titanium (MoTi).

Referring to FIG. 15, the transparent conductive layer 1170 is patterned to form a pixel electrode PE and a connection member CM. The pixel electrode PE contacts the drain electrode DE and overlaps the common electrode CE. The pixel electrode PE has an opening forming a slit portion SP extending in a direction. The connection member CM contacts the common electrode CE and the common line CL so that the common electrode CE and the common line CL are electrically connected to each other.

The pixel electrode PE and the connection member CM may include a transparent conductive material, such as indium tin oxide (ITO), indium zinc oxide (IZO) and etc. In addition, the pixel electrode PE and the connection member CM may include titanium (Ti) and/or molybdenum titanium (MoTi).

According to the embodiment, an oxide semiconductor layer does not remain under a data line. Thus, problems due to an active protrusion may be prevented.

Furthermore, an active pattern is exposed after a gate pad is exposed in the process of etching an etch-stop layer to expose the active pattern and the gate pad. Thus, damage to the active pattern may be prevented. Furthermore, the above processes may be performed without an additional mask by using half-tone light exposure.

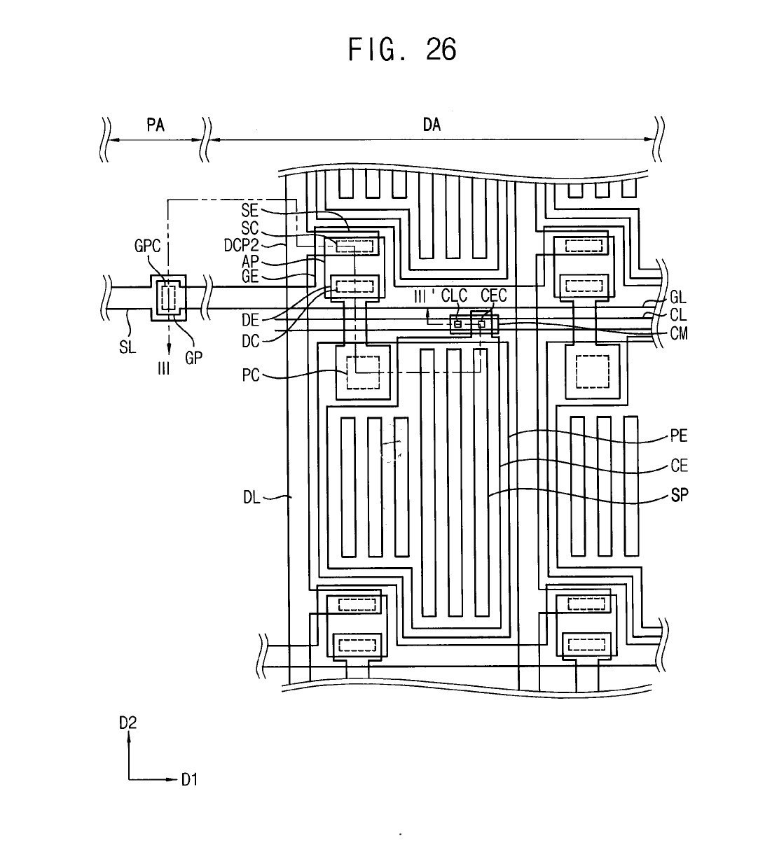

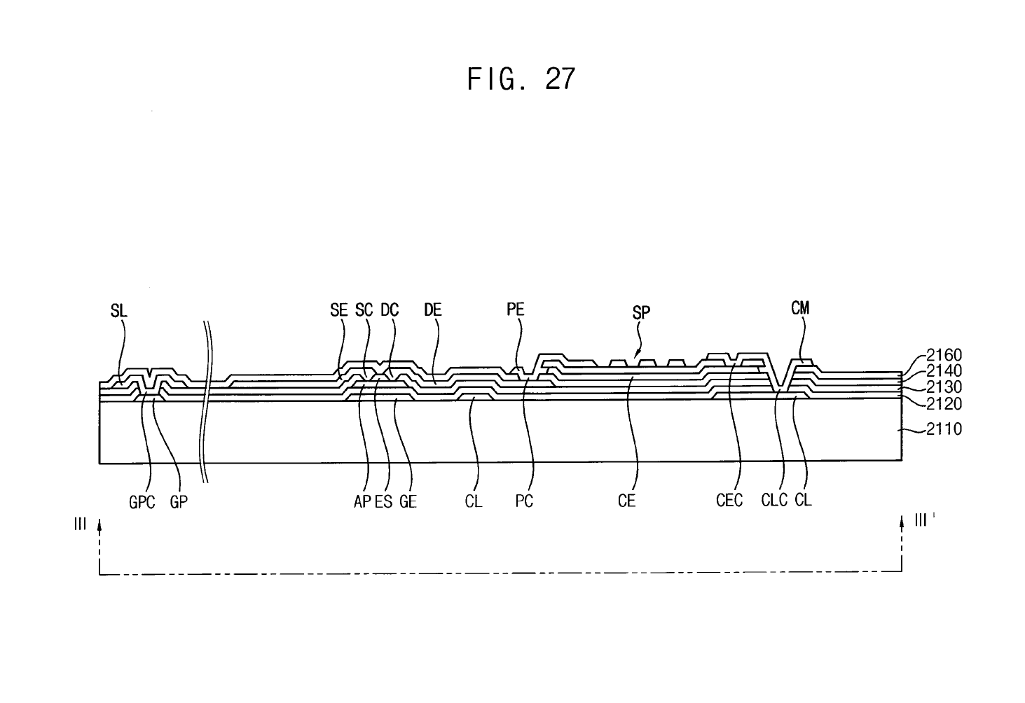

FIG. 26 is a plan view illustrating a thin film transistor substrate according to an exemplary embodiment of the inventive concept. FIG. 27 is a cross-sectional view taken along the line III-III′ of FIG. 26.

Referring to FIGS. 1, 26 and 27, a thin film transistor substrate may be a display substrate of a liquid crystal display panel for a liquid crystal display device. For example, the liquid crystal display panel may include the display substrate, an opposing substrate facing the display substrate and a liquid crystal layer interposed between the display substrate and the opposing substrate.

The thin film transistor substrate may include a display area DA and a peripheral area PA surrounding the display area DA. An array of a thin film transistor TFT is disposed in the display area DA.

The thin film transistor TFT is electrically connected to a gate line GL and a data line DL. A drain electrode of the thin film transistor TFT is electrically connected to a pixel electrode PE. The pixel electrode PE forms a liquid crystal capacitor LC with a common electrode CE electrically connected to a common line CL.

A gate driver GD providing a gate signal to the gate line GL and a data driver DD providing a data line to the data line DL may be disposed in the peripheral area PA. The gate driver GD and the data driver DD may be connected to an external control substrate to receive a driving signal.

In the embodiment, the gate driver GD may include a thin film transistor integrated on a base substrate. Thus, the gate driver GD may be formed through the same process as the thin film transistor TFT of the display area DA. The data driver DD may be integrated on the base substrate, or may be mounted on a tape carrier package, a flexible printed circuit board or the like.

The thin film transistor TFT includes a gate electrode GE, an active pattern AP, a source electrode SE and a drain electrode DE.

The gate line GL extends in a first direction D1, and the data line DL extends in a second direction D2, in a plan view. The first direction D1 intersects with the second direction D2. Furthermore, the first direction D1 may be substantially perpendicular to the second direction D2.

The gate line GL is electrically connected to the gate electrode GE. For example, the gate electrode GE may protrude from the gate line GL in the second direction D2. In another embodiment, a portion of the gate line GL may overlap the active pattern AP to function as the gate electrode GE so that the gate electrode GE may not protrude from the gate line GL.

An end of the gate line GL is connected to a gate pad GP. The gate pad GP is disposed in the peripheral area surrounding the display area DA. A gate signal is applied to the gate line GL through the gate pad GP. The gate pad GP contacts a signal line SL transmitting the gate signal. The signal line SL may be electrically connected to a drain electrode of the thin film transistor of the gate driver GD.

The thin film transistor substrate further includes a common line CL electrically connected to the common electrode CE to provide a common voltage to the common electrode CE. The common line CL may be disposed in the same layer as the gate line GL.

The thin film transistor substrate further includes a gate insulation layer 2120 that covers the gate electrode GE, the gate line GL and the common line CL.

The active pattern AP overlaps the gate electrode GE. The active pattern AP is disposed on the gate insulation layer 2120. The active pattern AP includes an oxide semiconductor. When a gate voltage is applied to the gate electrode GE, the active pattern AP becomes a conductor to function as a channel.

The thin film transistor substrate further includes an etch-stop layer 2130 covering the active pattern AP.

The source electrode SE and the drain electrode DE are spaced apart from each other, and contact the active pattern AP, respectively. The source electrode SE and the drain electrode DE are disposed on the etch-stop layer 2130.

The etch-stop layer 2130 has a first through hole SC and a second through hole DC. The source electrode SEcontacts the active pattern AP through the first through hole SC. In addition, the drain electrode DE contacts the active pattern AP through the second through hole DC.

The signal line SL may be disposed in the same layer as the source electrode SE. The signal line SL contacts the gate pad GP through a contact hole formed through the gate insulation layer 2120.

In an embodiment, the signal line SL of the gate driver GD is directly connected to the gate pad GP unlike a conventional thin film transistor substrate that uses a transparent conductive pattern as a bridge. Thus, a space for the bridge is not necessary. Thus, a bezel of a display panel including the thin film transistor substrate may be reduced. Furthermore, connection failure due to damage of the bridge or inflow of static electricity through the bridge may be prevented.

The thin film transistor substrate further includes a first passivation layer 2140 covering the thin film transistor. The first passivation layer 2140 may include an inorganic insulating material. The common electrode CE is disposed on the first passivation layer 2140. The thin film transistor substrate further includes a second passivation layer 2160 covering the common electrode CE. The pixel electrode PE is disposed on the second passivation layer 2160.

In the embodiment, the pixel electrode PE is disposed on the common electrode CE. However, the pixel electrode PE may be disposed under the common electrode CE in another embodiment. Furthermore, the common electrode CE may be formed on an opposing substrate spaced apart from the thin film transistor substrate in another embodiment.

The pixel electrode PE is disposed on the second passivation layer 2160. The pixel electrode PE has a slit portion SP. The slit portion SP may extend, for example, in the second direction D2, and may includes a plurality of slits arranged in the first direction D1. The pixel electrode PE overlaps the common electrode CE to form an electric field depending on a voltage applied thereto so as to control an arrangement of liquid crystal molecules disposed thereon. The pixel electrode PE includes a pixel contact PC passing through the second passivation layer 2160 and the first passivation layer 2140 to contact the drain electrode DE.

The common electrode CE and the pixel electrode PE may include a transparent conductive material such as indium zinc oxide, indium tin oxide or the like.

The thin film transistor substrate further includes a connection member CM electrically connecting the common electrode CE to the common line CL. The connection member CM may be disposed in the same layer as the pixel electrode PE. The connection member CM includes a common electrode contact CEC and a common line contact CLC. The common electrode contact CEC passes through the second passivation layer 1160 to contact the common electrode CE, and the common line contact CLC passes through the second passivation layer 2160, the first passivation layer 2140, the etch-stop layer 2130 and the gate insulation layer 2120 to contact the common line CL.

In another embodiment, the thin film transistor substrate may further include a color filter and/or a black matrix disposed on the passivation layer 2140.

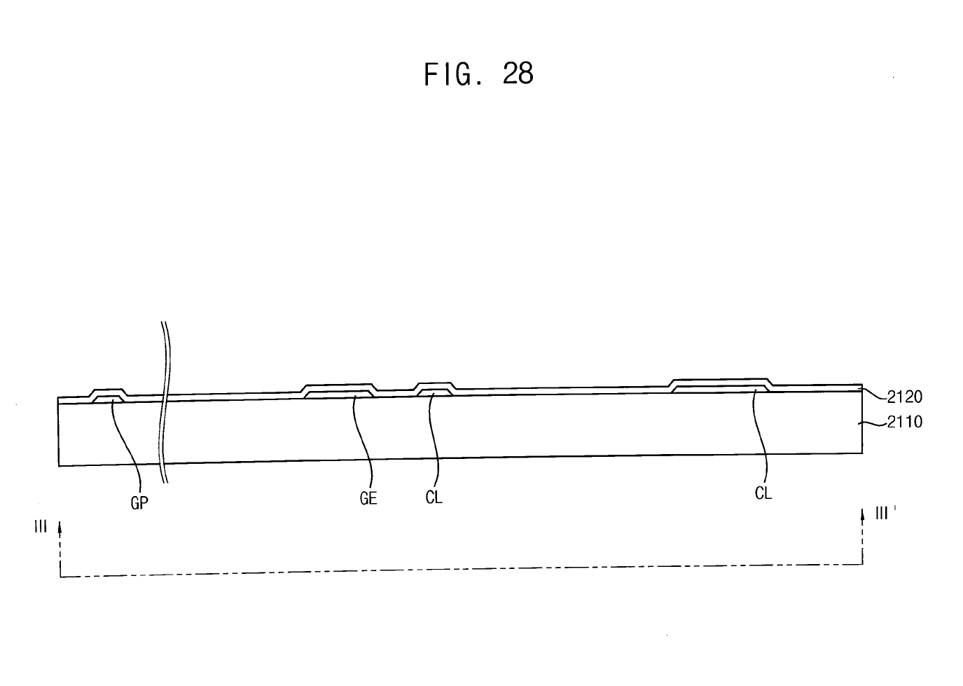

FIGS. 28 to 36 are cross-sectional views illustrating a method of manufacturing the thin film transistor substrate of FIG. 27.

Referring to FIG. 28, a gate metal layer is formed on a base substrate 2110, and patterned to form a gate metal pattern including a gate electrode GE, a common line CL and a gate pad GP. The gate metal pattern further includes a gate line continuously connected to the gate electrode GE and the gate pad GP.

Examples of the base substrate 2110 may include a glass substrate, a quartz substrate, a silicon substrate, a plastic substrate and the like.

Examples of a material that may be used for the gate metal layer may include copper, silver, chromium, molybdenum, aluminum, titanium, manganese, or an alloy thereof. The gate metal layer may have a single-layered structure or may have a multiple-layered structure including different materials. For example, the gate metal layer may include a copper layer and a titanium layer disposed on and/or under the copper layer.

In another embodiment, the gate metal layer may include a metal layer and a conductive oxide layer disposed on and/or under the metal layer. For example, the gate metal layer may include a copper layer and a conductive oxide layer disposed on and/or under the copper layer. Examples of a material that may be used for the conductive oxide layer may include indium zinc oxide, indium tin oxide, gallium zinc oxide, and zinc aluminum oxide.

Thereafter, a gate insulation layer 2120 is formed to cover the gate metal pattern. Examples of a material that may be used for the gate insulation layer 2120 may include silicon nitride, silicon oxide, aluminum oxide, hafnium oxide, titanium oxide and the like. The gate insulation layer 2120 may have a single-layered structure or a multiple-layered structure. For example, the gate insulation layer 2120 may include a lower insulation layer including silicon nitride and an upper insulation layer including silicon oxide.

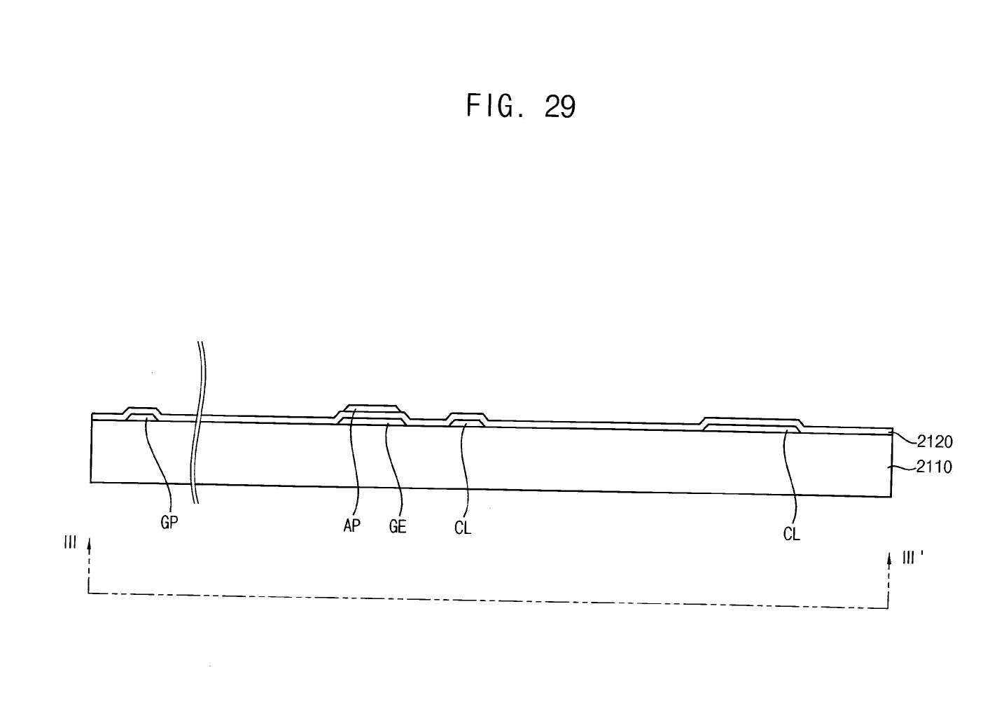

Referring to FIG. 29, an active layer is formed on the gate insulation layer 2120 and patterned to form an active pattern AP. The active pattern AP includes an oxide semiconductor. Examples of the oxide semiconductor may include zinc oxide, zinc tin oxide, indium zinc oxide, indium oxide, titanium oxide, indium gallium zinc oxide, indium zinc tin oxide and the like. The active pattern AP overlaps the gate electrode GE.

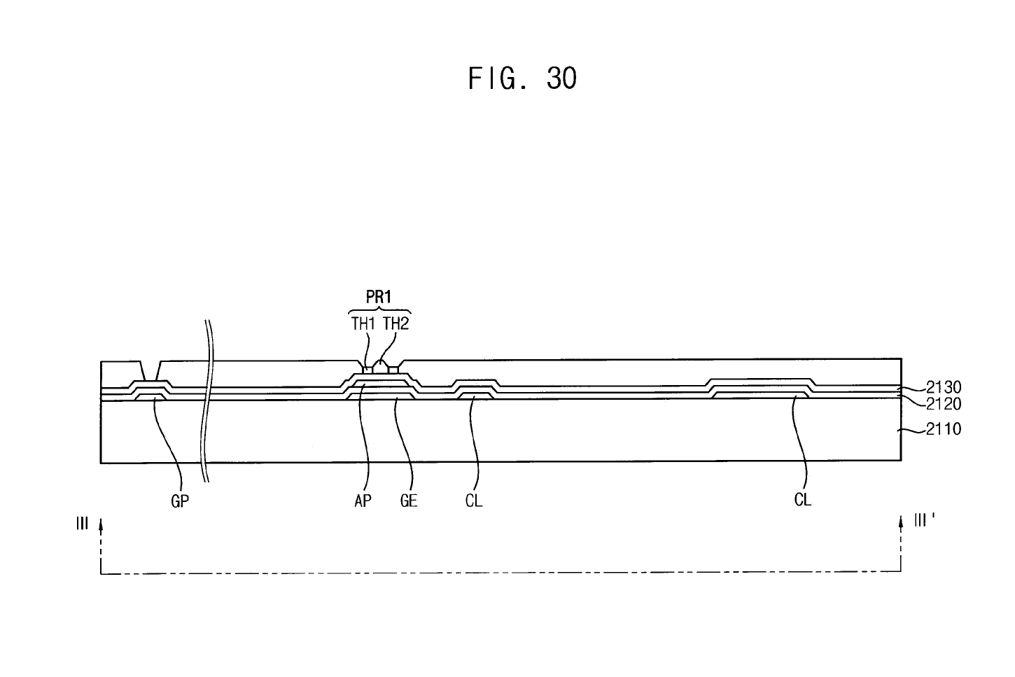

Referring to FIG. 30, an etch-stop layer 2130 is formed to cover the active pattern AP. Examples of a material that may be used for the etch-stop layer 2130 may include silicon nitride, silicon oxide, aluminum oxide, hafnium oxide, titanium oxide and the like.

A first photoresist pattern PR1 is formed on the etch-stop layer 2130. The first photoresist pattern PR1 may be formed on substantially an entire portion of the etch-stop layer 2130.

The first photoresist pattern PR1 has through holes exposing a portion of the etch-stop layer 2130. For example, the through hole may overlap the gate pad GP.

The first photoresist pattern PR1 includes a first thickness portion TH1 and a second thickness portion TH2 thicker than the first thickness portion TH1. The first thickness portion TH1 overlaps the active pattern AP.

For example, a photoresist is coated, and exposed to a light through a half-tone exposure and developed by a developing solution to form the first photoresist pattern PR1.

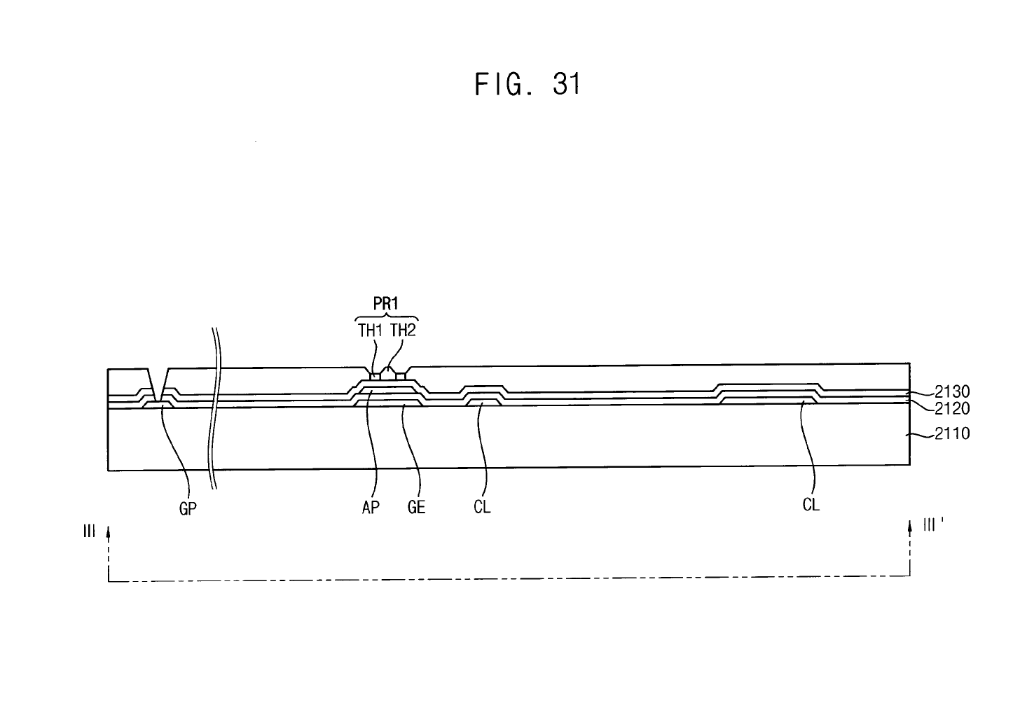

Referring to FIG. 31, the etch-stop layer 2130 and the gate insulation layer 2120 are etched by using the first photoresist pattern mask PR1 as a mask. Thus, the gate pad GP is exposed.

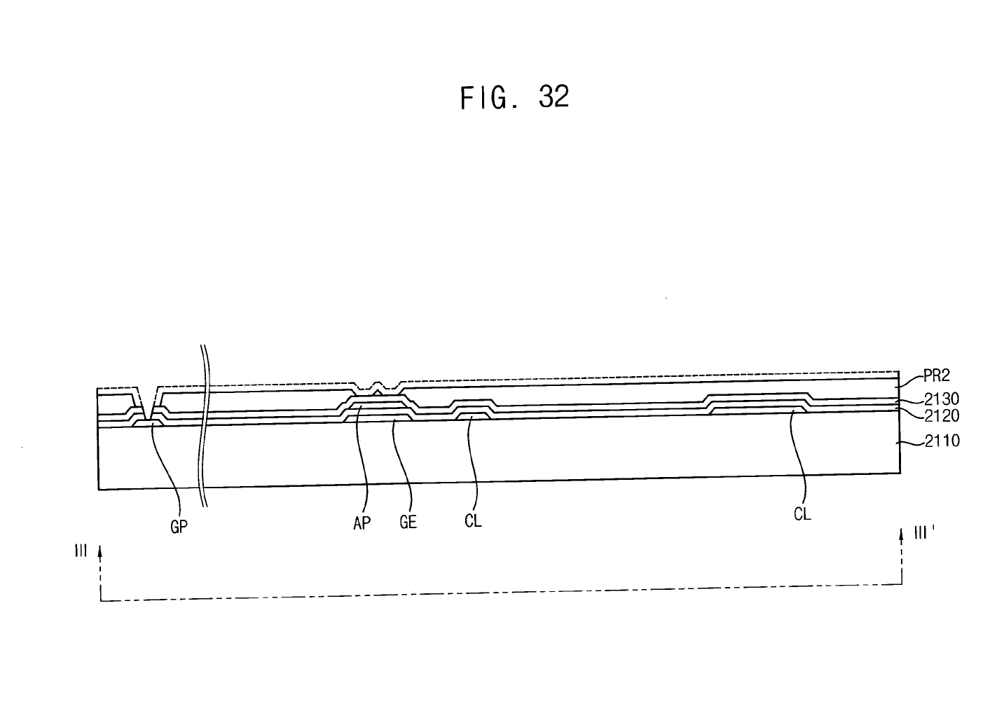

Referring to FIG. 32, the first photoresist pattern PR1 is partially removed, for example, through an ashing process. As a result, the first thickness portion TH1 is removed, and the second thickness portion TH2 partially remains to form a second photoresist pattern PR2.

The second photoresist pattern PR2 has a through hole exposing the etch-stop layer 2130 overlapping the active pattern AP. Furthermore, through the ashing process, an upper surface of the etch-stop layer 2130 adjacent to the gate pad GP may be exposed.

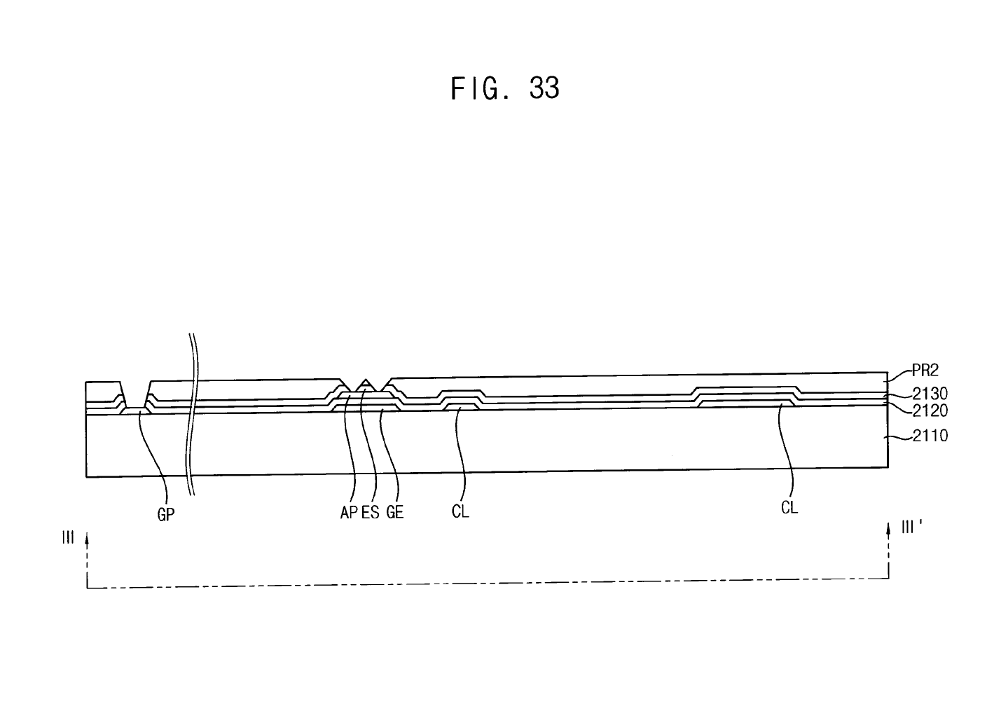

Referring to FIG. 33, the etch-stop layer 2130 is etched by using the second photoresist pattern PR2 as a mask to form a first through hole SC and a second through hole DC exposing the active pattern AP.

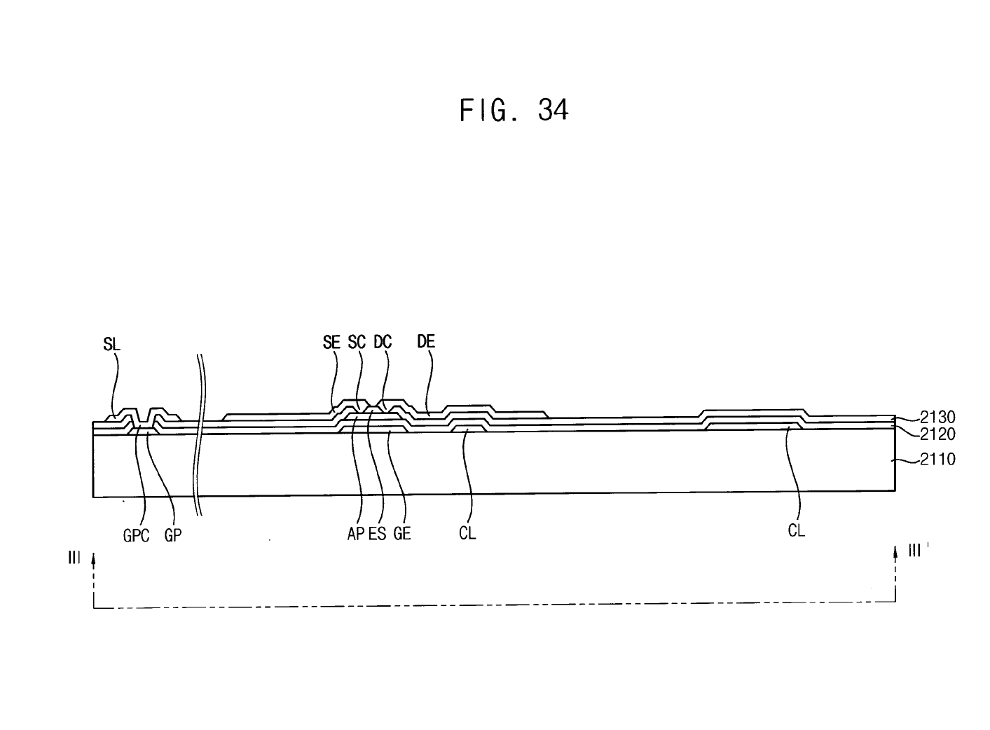

Referring to FIG. 34, a data metal layer is formed on the etch-stop layer 2130 after the second photoresist pattern PR2 is removed.

In an embodiment, the data metal layer may include titanium. Particularly, the data metal layer may have a titanium single-layered structure or a multiple-layered structure further including a different metal layer. For example, the data metal layer may have a double-layered structure of a lower titanium layer and an upper copper layer, or a triple-layered structure of titanium/aluminum/titanium.

In another embodiment, the data metal layer may have a single-layered structure of a transparent conductive oxide. According to a conventional method, a data line does not include a transparent conductive oxide as a main layer because of low conductivity. In the embodiment, a source electrode, a drain electrode and a portion of a data line may be formed from a transparent conductive oxide. The data metal layer including a transparent conductive oxide may be etched by the same etchant as a pixel electrode.

Thus, etchants required for manufacturing a thin film transistor substrate may be reduced if the data metal layer includes a transparent conductive oxide.

The data metal layer is patterned to form a data metal pattern including a source electrode SE, a drain electrode DE and a signal line SL.

The source electrode SE contacts with the active pattern AP through the first through hole SC. The drain electrode DE contacts with the active pattern AP through the second through hole DC.

As illustrated in FIG. 1, the thin film transistor substrate according to an exemplary embodiment includes a thin film transistor constituting the gate driver GD, and the thin film transistor may be formed through the same process as the thin film transistor in the display area DA. Thus, the signal line SL may be a portion of a drain electrode of the thin film transistor in the gate driver GD, or may be connected to the drain electrode of thin film transistor in the gate driver GD.

In the embodiment, the signal line SL includes a gate pad contact GPC passing through the gate insulation layer 1120 and the etch-stop layer 1130 to contact the gate pad GP. Thus, a width of a bezel of a display panel may be reduced. Furthermore, reliability deterioration due to using a bridge may be prevented.

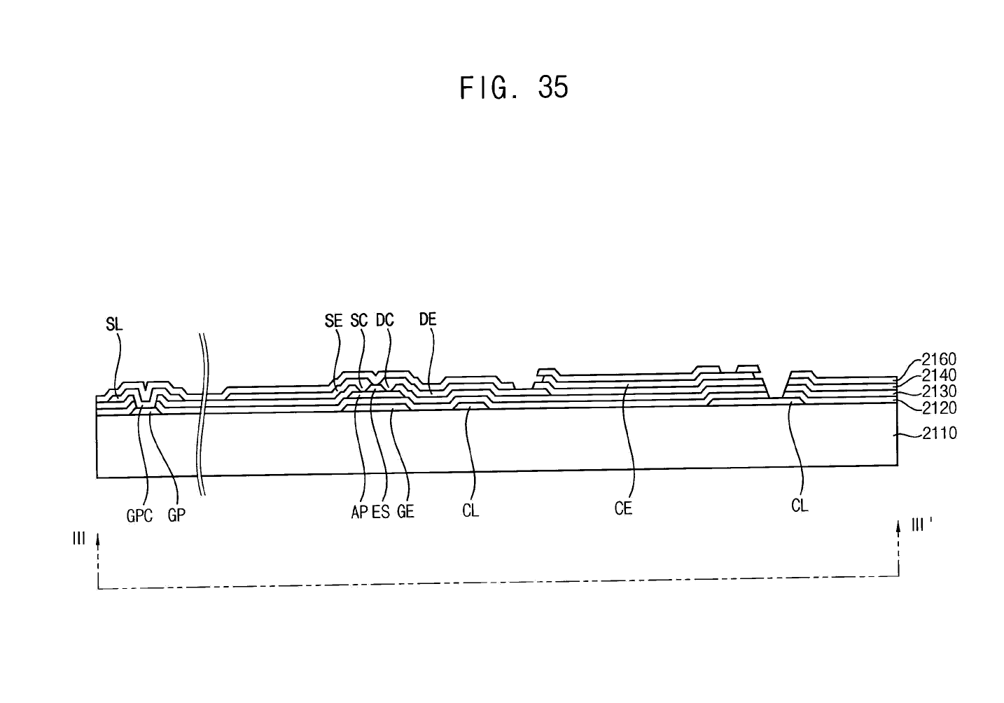

Referring to FIG. 35, a first passivation layer 2140, a common electrode CE and a second passivation layer 2160 are formed on the base substrate on which the data metal pattern is formed.

The first passivation layer 2140 may include an inorganic insulating material. The common electrode CE is disposed on the first passivation layer 2140. The thin film transistor substrate further includes a second passivation layer 2160 covering the common electrode CE. The second passivation layer 2160 may include an inorganic insulation material such as silicon oxide, silicon nitride or the like.

The first passivation layer 2140, the common electrode CE and the second passivation layer 2160 are formed by the same mask.

The common electrode CE may be formed by wet-etching process. The first passivation layer 2140 and the second passivation layer 2160 may be formed by dry-etching process. Therefore, the common electrode CE may form an under-cut structure with the first passivation layer 2140 and the second passivation layer 2160.

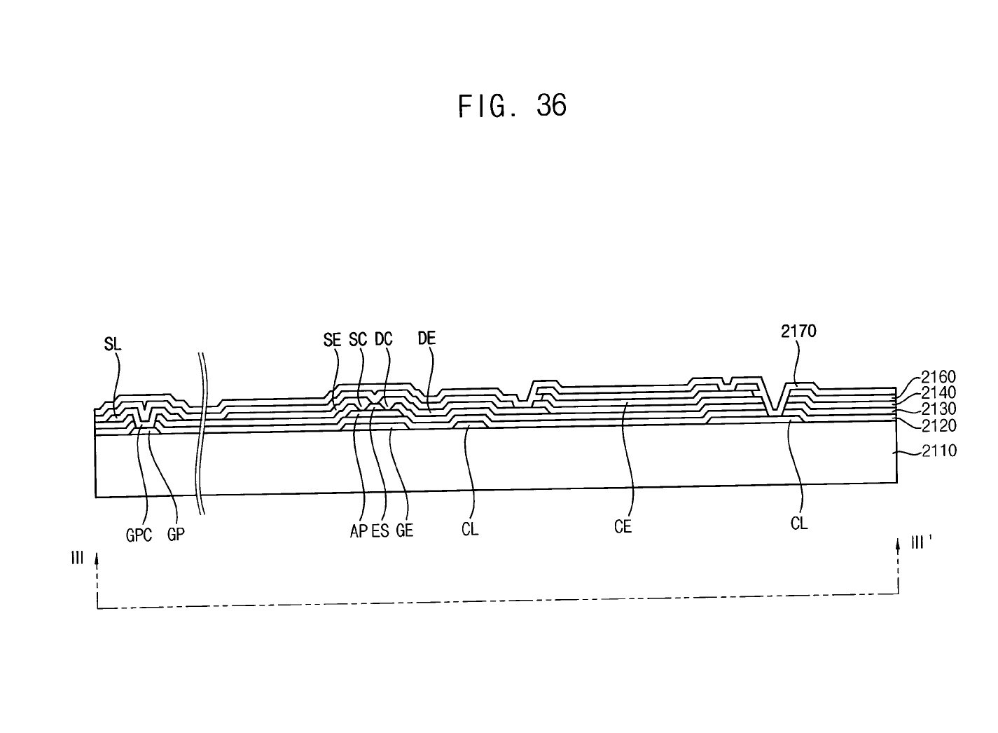

Referring to FIG. 36, a transparent conductive layer 2170 is formed on the base substrate on which the second passivation layer 2160 is formed.

The transparent conductive layer 2170 may include a transparent conductive material, such as indium tin oxide (ITO), indium zinc oxide (IZO) and etc. In addition, the transparent conductive layer 2170 may include titanium (Ti) and/or molybdenum titanium (MoTi).

Referring to FIG. 26, the transparent conductive layer 2170 is patterned to form a pixel electrode PE and a connection member CM. The pixel electrode PE contacts the drain electrode DE and overlaps the common electrode CE. The pixel electrode PE has an opening forming a slit portion SP extending in a direction. The connection member CM contacts the common electrode CE and the common line CL so that the common electrode CE and the common line CL are electrically connected to each other.

The pixel electrode PE and the connection member CM may include a transparent conductive material, such as indium tin oxide (ITO), indium zinc oxide (IZO) and etc. In addition, the pixel electrode PE and the connection member CM may include titanium (Ti) and/or molybdenum titanium (MoTi).

According to the embodiment, an oxide semiconductor layer does not remain under a data line. Thus, problems due to an active protrusion may be prevented.

Furthermore, an active pattern is exposed after a gate pad is exposed in the process of etching an etch-stop layer to expose the active pattern and the gate pad. Thus, damage to the active pattern may be prevented. Furthermore, the above processes may be performed without an additional mask by using half-tone light exposure.

According to the present exemplary embodiment, an oxide semiconductor layer does not remain under a data line. Thus, problems due to an active protrusion may be prevented. In addition, the first passivation layer is not an organic layer but an inorganic insulating layer. Therefore, the number of mask required for forming the organic layer may be decreased.

In addition, an active pattern is exposed after a gate pad is exposed in the process of etching an etch-stop layer to expose the active pattern and the gate pad. Thus, damage to the active pattern may be prevented. Furthermore, the above processes may be performed without an additional mask by using half-tone light exposure.

The foregoing is illustrative of the present invention and is not to be construed as limiting thereof. Although a few exemplary embodiments of the present invention have been described, those skilled in the art will readily appreciate that many modifications are possible in the exemplary embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific exemplary embodiments disclosed, and that modifications to the disclosed exemplary embodiments, as well as other exemplary embodiments, are intended to be included within the scope of the appended claims. The present inventive concept is defined by the following claims, with equivalents of the claims to be included therein.

What is claimed is:

1. A thin film transistor substrate comprising:
a gate metal pattern comprising a gate line extending in a first direction and a gate electrode electrically connected to the gate line;
an active pattern overlapping the gate electrode;
an etch-stop layer disposed on the active pattern and having a first through hole and a second through hole adjacent to the first through hole;
a data metal pattern comprising a data line extending in a second direction crossing the first direction, a source electrode electrically connected to the active pattern through the first through hole and a drain electrode electrically connected to the active pattern through the second through hole; and
a first passivation layer disposed on the data metal pattern.

2. The thin film transistor substrate of claim 1, further comprising:
a gate pad disposed on the same layer as the gate metal pattern and electrically connected to the gate line; and
a signal line disposed on the same layer as the data metal pattern and contacted with the gate pad to apply a gate signal to the gate pad.

3. The thin film transistor substrate of claim 2, further comprising:
a gate insulation layer covering the gate line and the gate electrode; and
the etch-stop layer covers the gate insulation layer and the active pattern.

4. The thin film transistor substrate of claim 1, the etch-stop layer comprises a silicon oxide or a silicon nitride.

5. The thin film transistor substrate of claim 1, the data metal pattern has a single-layered structure or a multiple-layered structure comprising titanium.

6. The thin film transistor substrate of claim 1, the active pattern comprises an oxide semiconductor.

7. The thin film transistor substrate of claim 1, the first passivation layer comprises an inorganic insulating material.

8. The thin film transistor substrate of claim 6, further comprising:
a common electrode disposed on the first passivation layer;
a second passivation layer disposed on the common electrode; and
a pixel electrode disposed on the second passivation layer and electrically connected to the drain electrode.

9. The thin film transistor substrate of claim 8, wherein the common electrode forms an under-cut structure with the second passivation layer.

10. A method for manufacturing a thin film transistor substrate, the method comprising:
forming a gate metal pattern on a base substrate, the gate metal pattern comprising a gate line extending in a first direction and a gate electrode electrically connected to the gate line;
forming a gate insulation layer covering the gate line and the gate electrode;
forming an active pattern overlapping the gate electrode;
forming an etch-stop layer covering the gate insulation layer and the active pattern;
forming a data metal pattern comprising a data line extending in a second direction crossing the first direction, a source electrode electrically connected to the active pattern through the first through hole and a drain electrode electrically connected to the active pattern through the second through hole; and
forming a first passivation layer on the data metal pattern.

11. The method of claim 10, further comprising:
forming a common electrode on the first passivation layer;
forming a second passivation layer on the common electrode; and
forming a pixel electrode on the second passivation layer, the pixel electrode being electrically connected to the drain electrode.

12. The method of claim 11, the first passivation layer and the common electrode are formed by the same mask.

13. The method of claim 11, the first passivation layer, the common electrode and the second passivation layer are formed by the same mask.

14. The method of claim 13, the common electrode forms an under-cut structure with the second passivation layer.

15. The method of claim 10, the gate metal pattern further comprises a gate pad electrically connected to the gate line, and the data metal pattern further comprises a signal line contacted with the gate pad to apply a gate signal to the gate pad.

16. The method of claim 15, further comprising:
forming a first photoresist pattern on the etch-stop layer, the first photoresist pattern having through holes overlapping the gate pad, the first photoresist pattern comprising a first thickness portion and a second thickness portion thinner than the first thickness portion;
etching the etch-stop layer and the gate insulation layer by using the first photoresist pattern as a mask to expose the gate pad;
partially removing the first photoresist pattern to form a second photoresist pattern having through holes overlapping the active pattern; and
etching the etch-stop layer by using the second photoresist pattern as a mask to expose a portion of the active pattern.

17. The method of claim 10, the etch-stop layer comprises a silicon oxide or a silicon nitride.

18. The method of claim 10, the data metal pattern has a single-layered structure or a multiple-layered structure comprising titanium.

19. The method of claim 10, the active pattern comprises an oxide semiconductor.

20. The method of claim 10, the first passivation layer comprises an inorganic insulating material.
